(19) United States
(12) Patent Application Publication
(10) Pub. No.: US 2025/0056957 A1
(43) Pub. Date: Feb. 13, 2025

(54) ELECTRONIC APPARATUS INCLUDING ORGANIC PHOTODETECTOR

(71) Applicant: Samsung Display Co., Ltd., Yongin-Si, Gyeonggi-Do (KR)

(72) Inventors: Kiwoong Kim, Yongin-si, (KR); Soungwook Kim, Yongin-si, (KR); Hwasook Ryu, Yongin-si, (KR); Minsoo Choi, Yongin-si, (KR); Seokgyu Yoon, Yongin-si, (KR)

(21) Appl. No.: 18/430,660

(22) Filed: Feb. 2, 2024

(30) Foreign Application Priority Data
Jul. 26, 2023 (KR) 10-2023-0097795

(51) Int. Cl. H10K 39/34; H10K 85/60; H10K 101/30

(52) U.S. Cl. CPC H10K 39/34; H10K 85/653; H10K 85/654; H10K 85/655; H10K 85/6572; H10K 2101/30

(57) ABSTRACT

Provided is an electronic apparatus including an organic photodetector and a light-emitting device, wherein a mean square roughness (R_{q}) value of a surface of an activation layer of the organic photodetector in a direction of contact with an electron transport region is 9 nm or more.

### CROSS-REFERENCE TO RELATED APPLICATION

This application is based on and claims priority, under 35 U.S.C. § 119, to Korean Patent Application No. 10-2023-0097795 filed on Jul. 26, 2023 in the Korean Intellectual Property Office, the disclosure of which is incorporated by reference herein in its entirety.

### BACKGROUND

### 1. Field

One or more embodiments relate to an electronic apparatus including an organic photodetector.

### 2. Description of the Related Art

Photoelectric devices are devices that convert light to electrical signals and include a photodiode and a phototransistor. Photoelectric devices may be applied to an image sensor, a solar cell, an organic light-emitting device, and the like.

Silicon is commonly used in photodiodes today. However, as the size of pixels decreases, an absorption region may decrease, thus deteriorating sensitivity. Accordingly, organic materials that may replace silicon are being studied.

As organic materials have a large extinction coefficient and may selectively absorb light in a specific wavelength region according to their molecular structures, organic materials may replace photodiodes and color filters simultaneously, which may facilitate improvements in sensitivity and high integration.

An organic photodetector including such an organic material may be applied to, for example, a display apparatus or an image sensor.

An in-cell-type organic photodetector refers to a fusion device in which an organic light-emitting device and an organic photodetector are arranged in parallel.

### SUMMARY

One or more embodiments include an electronic apparatus including an organic photodetector having improved efficiency.

Additional aspects will be set forth in part in the description which follows and, in part, will be apparent from the description, or may be learned by practice of the presented embodiments of the disclosure.

According to one or more embodiments, an electronic apparatus includes
a substrate including a photodetection region and an emission region, an organic photodetector arranged on the photodetection region, and a light-emitting device arranged on the emission region, wherein the organic photodetector includes a first pixel electrode, a counter electrode facing the first pixel electrode, and a hole transport region, an activation layer, and an electron transport region sequentially arranged between the first pixel electrode and the counter electrode, the light-emitting device includes a second pixel electrode, the counter electrode facing the second pixel electrode, and the hole transport region, an emission layer, and the electron transport region sequentially arranged between the second pixel electrode and the counter electrode, the first pixel electrode and the activation layer are arranged in the photodetection region, the second pixel electrode and the emission layer are arranged in the emission region, the hole transport region, the electron transport region, and the counter electrode are arranged throughout the photodetection region and the emission region, and the electron transport region and the activation layer of the organic photodetector are in contact with each other, and a mean square roughness (R_{q}) value of a surface of the activation layer that is closest to the electron transport region is 9 nm or more.

In an embodiment, the hole transport region may include a hole injection layer, a hole transport layer, an electron blocking layer, an auxiliary layer, or any combination thereof.

In an embodiment, the electron transport region may include a buffer layer, a hole blocking layer, an electron transport layer, an electron injection layer, or any combination thereof.

In an embodiment, the activation layer may include a layer including a p-type semiconductor compound and a layer including an n-type semiconductor compound, and the layer including the n-type semiconductor compound may be in contact with the electron transport region.

In an embodiment, the electron transport region of the organic photodetector may include a buffer layer, a hole blocking layer, an electron transport layer, an electron injection layer, or any combination thereof, and one layer of the electron transport region may be in contact with the activation layer.

In an embodiment, the electron transport region of the organic photodetector may include a buffer layer, a hole blocking layer, an electron transport layer, an electron injection layer, or any combination thereof, and a mean square roughness (R_{q}) value of a surface of each layer of the electron transport region may be 9 nm or more.

In an embodiment, mean square roughness (R_{q}) values of top and bottom surfaces of the counter electrode above the first pixel electrode may each be 9 nm or more.

In an embodiment, mean square roughness (R_{q}) values of top and bottom surfaces of the counter electrode above the second pixel electrode may each be less than 5 nm.

In an embodiment, the activation layer may be a mixed layer including a p-type semiconductor compound and an n-type semiconductor compound.

In an embodiment, the activation layer may include a layer including a p-type semiconductor compound and a layer including an n-type semiconductor compound, the layer including the p-type semiconductor compound and the layer including the n-type semiconductor compound are in direct contact with each other, and a mean square roughness (R_{q}) value of a surface of the layer including the p-type semiconductor compound in contact with the layer including the n-type semiconductor compound may be less than 5 nm.

In an embodiment, the electron transport region and the emission layer of the light-emitting device may be in contact with each other, and a mean square roughness (R_{q}) value of a surface of the emission layer that is closest to the electron transport region may be less than 5 nm.

In an embodiment, the activation layer may include a layer including an n-type semiconductor compound, and a lowest unoccupied molecular orbital (LUMO) energy value of the layer may be greater than −4.50 eV and less than −3.20 eV.

In an embodiment, the activation layer may include a layer including a p-type semiconductor compound and a layer including an n-type semiconductor compound, the layer including the n-type semiconductor compound may be in contact with the electron transport region arranged between the first pixel electrode and the counter electrode, and a difference between a LUMO energy value of a layer in the electron transport region in contact with the layer including the n-type semiconductor compound and a LUMO energy value of the layer including the n-type semiconductor compound may be 0.3 eV or more.

In an embodiment, the LUMO energy value of the layer in the electron transport region in contact with the layer including the n-type semiconductor compound may be greater than the LUMO energy value of the layer including the n-type semiconductor compound.

In an embodiment, the layer in the electron transport region in contact with the layer including the n-type semiconductor compound may be a buffer layer or an electron transport layer.

In an embodiment, the electron transport region arranged throughout the photodetection region and the emission region may include an electron transport layer, mean square roughness (R_{q}) values of top and bottom surfaces of the electron transport layer of the light-emitting device may each be less than 5 nm, and mean square roughness (R_{q}) values of top and bottom surfaces of the electron transport layer of the organic photodetector may each be 9 nm or more.

In an embodiment, a thickness of the electron transport layer of the light-emitting device may be in a range of about 100 Å to about 3,000 Å.

In an embodiment, the activation layer may include a p-type semiconductor compound, and the p-type semiconductor compound may include a compound represented by Formula 1:

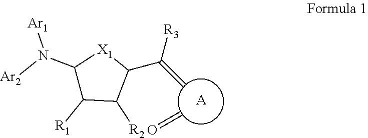

wherein, details of Formula 1 will be described below.

In an embodiment, the p-type semiconductor compound may include one of compounds below:

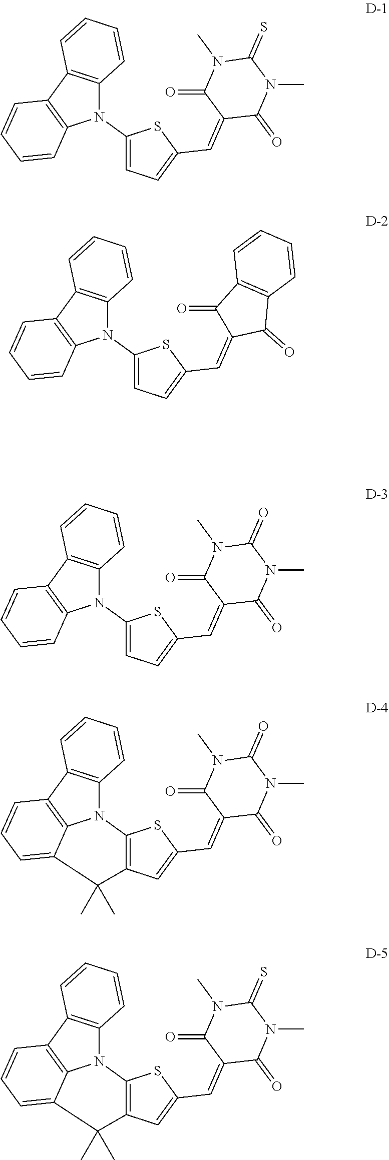 [SMILES: CN1C(=O)C(=Cc2ccc(-n3c4ccccc4c4ccccc43)s2)C(=O)N(C)C1=S ; O=C1C(=Cc2ccc(-n3c4ccccc4c4ccccc43)s2)C(=O)c2ccccc21 ; CN1C(=O)C(=Cc2ccc(-n3c4ccccc4c4ccccc43)s2)C(=O)N(C)C1=O ; CN1C(=O)C(=Cc2cc3c(s2)-n2c4ccccc4c4cccc(c42)C3(C)C)C(=O)N(C)C1=O ; CN1C(=O)C(=Cc2cc3c(s2)-n2c4ccccc4c4cccc(c42)C3(C)C)C(=O)N(C)C1=S]

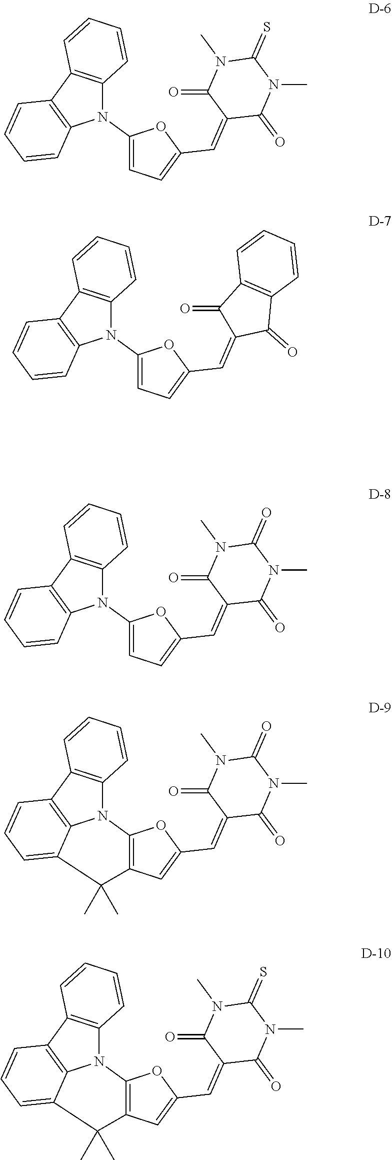 [SMILES: CN1C(=O)C(=Cc2ccc(-n3c4ccccc4c4ccccc43)o2)C(=O)N(C)C1=S ; O=C1C(=Cc2ccc(-n3c4ccccc4c4ccccc43)o2)C(=O)c2ccccc21 ; CN1C(=O)C(=Cc2ccc(-n3c4ccccc4c4ccccc43)o2)C(=O)N(C)C1=O ; CN1C(=O)C(=Cc2cc3c(o2)-n2c4ccccc4c4cccc(c42)C3(C)C)C(=O)N(C)C1=O ; CN1C(=O)C(=Cc2cc3c(o2)-n2c4ccccc4c4cccc(c42)C3(C)C)C(=O)N(C)C1=S]

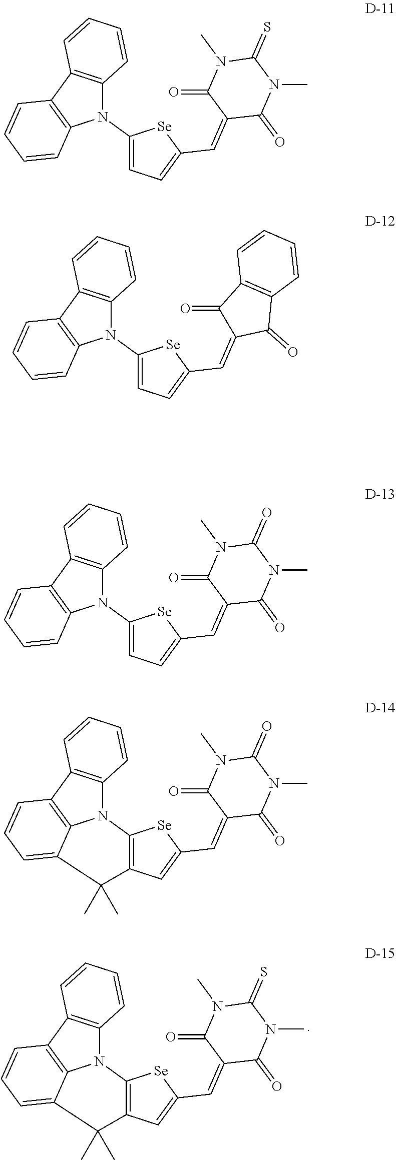 [SMILES: CN1C(=O)C(=Cc2ccc(-n3c4ccccc4c4ccccc43)[se]2)C(=O)N(C)C1=S ; O=C1C(=Cc2ccc(-n3c4ccccc4c4ccccc43)[se]2)C(=O)c2ccccc21 ; CN1C(=O)C(=Cc2ccc(-n3c4ccccc4c4ccccc43)[se]2)C(=O)N(C)C1=O ; CN1C(=O)C(=Cc2cc3c([se]2)-n2c4ccccc4c4cccc(c42)C3(C)C)C(=O)N(C)C1=O ; CN1C(=O)C(=Cc2cc3c([se]2)-n2c4ccccc4c4cccc(c42)C3(C)C)C(=O)N(C)C1=S]

In an embodiment, the activation layer may include an n-type semiconductor compound, and the n-type semiconductor compound may include a compound represented by Formula 2 or 3:

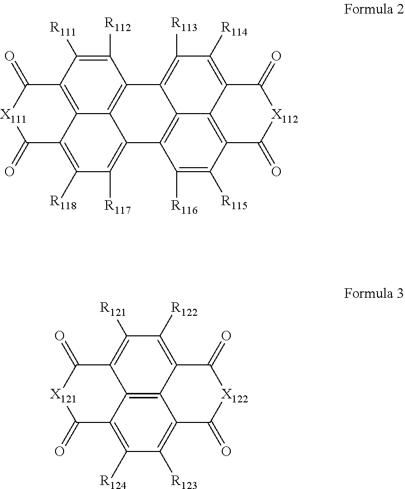

wherein, details of Formulae 2 and 3 will be described below.

In an embodiment, the n-type semiconductor compound may include one of compounds below:

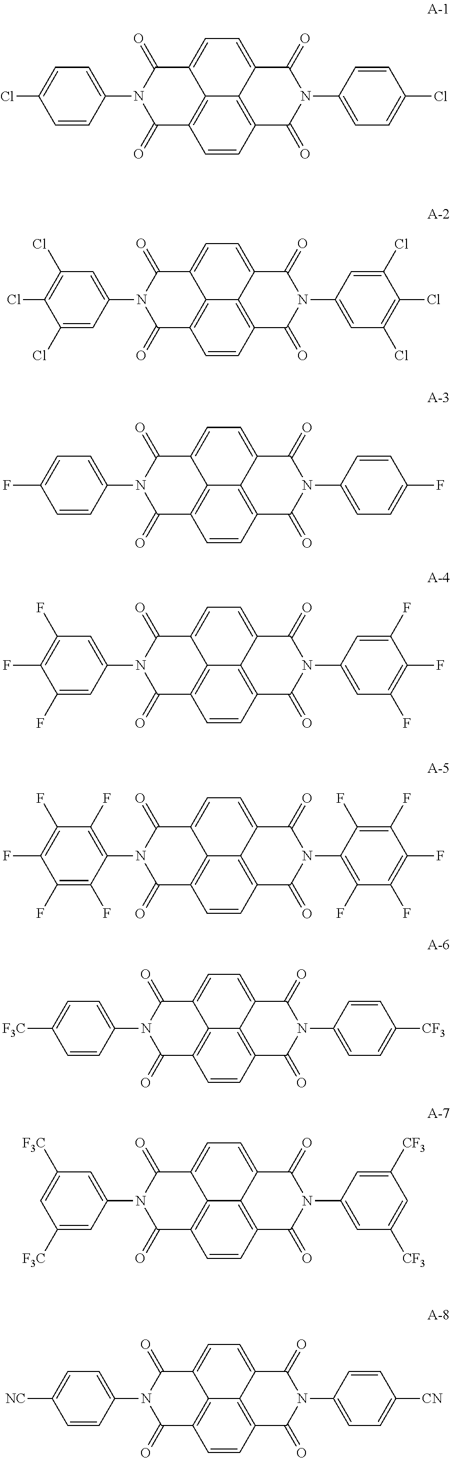

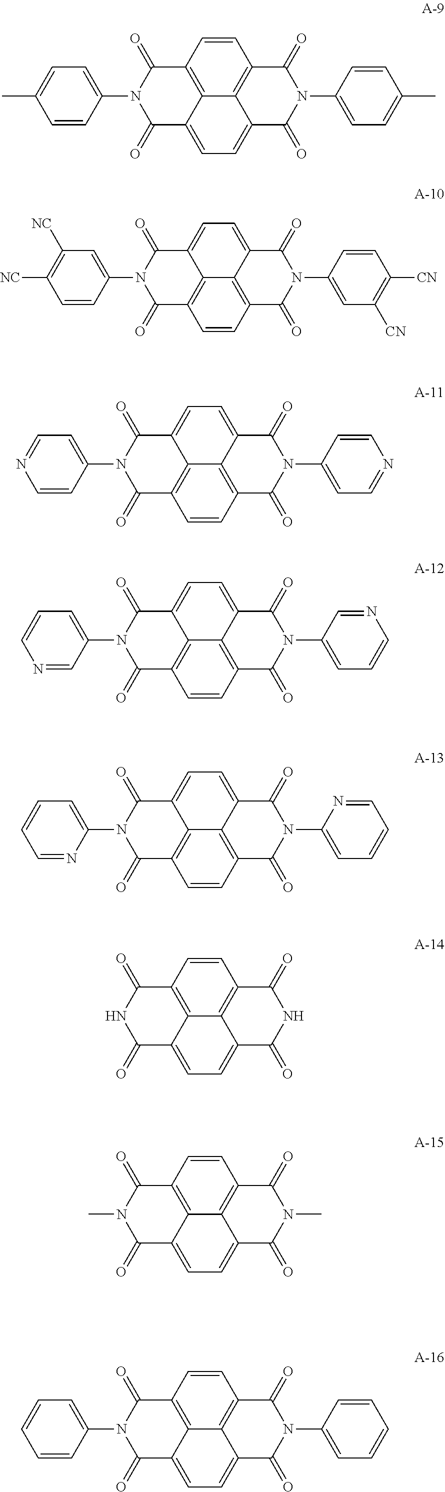

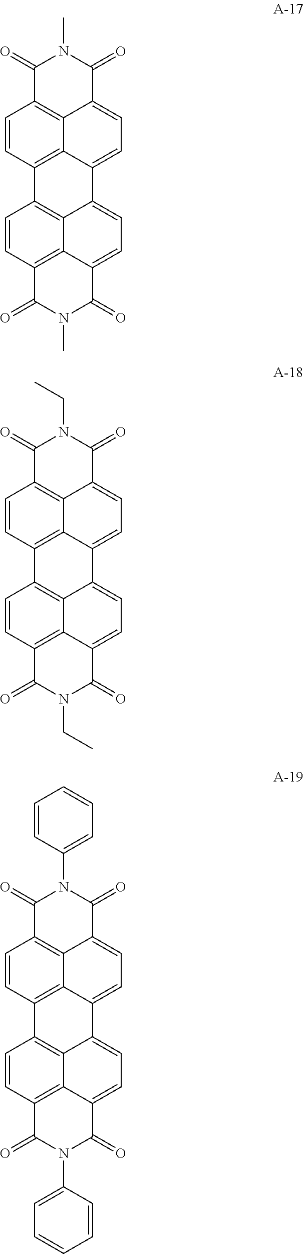

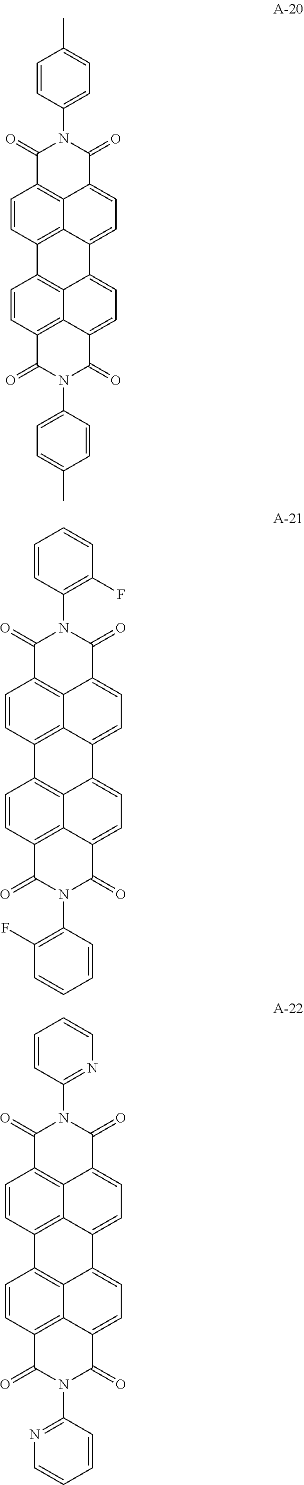

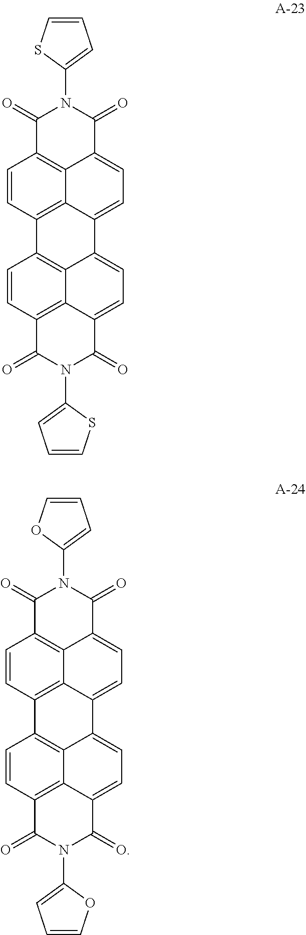

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of an organic photodetector included in an electronic apparatus according to an embodiment;

FIG. 2 is a schematic enlarged view of an oval portion in FIG. 1;

FIG. 3 is a schematic view of an electronic apparatus according to an embodiment;

FIG. 4 is a schematic view of an electronic apparatus according to an embodiment; and

FIGS. 5A and 5B are each a view of an electronic apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because the disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

An expression used in the singular encompasses the expression of the plural, unless it has a clearly different meaning in the context.

It will be understood that the terms “comprise”, “include”, “have”, and the like used herein specify the presence of stated features or components, but do not preclude the presence or addition of one or more other features or components.

It will be understood that when a layer, region, or component is referred to as being “on” or “onto” another layer, region, or component, it may be directly or indirectly formed on the other layer, region, or component. That is, for example, intervening layers, regions, or components may be present.

In descriptions with reference to the drawings, identical or corresponding components are assigned identical or like reference numerals, and overlapping descriptions thereof will be omitted.

Sizes of components in the drawings may be exaggerated for convenience of explanation. In other words, because sizes and thicknesses of components in the drawings are arbitrarily illustrated for convenience of explanation, the following embodiments are not limited thereto.

An in-cell-type organic photodetector refers to an electronic apparatus in which an organic light-emitting device and an organic photodetector are arranged in parallel. In the electronic apparatus, a hole transport region, an electron transport region, and a counter electrode may be commonly arranged throughout a photodetection region and an emission region.

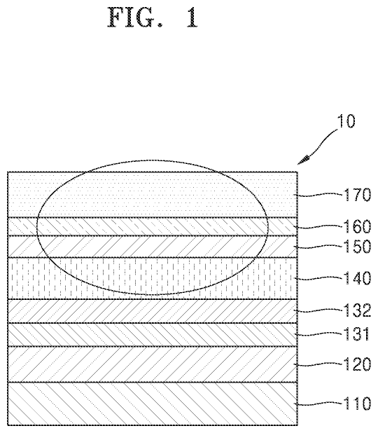

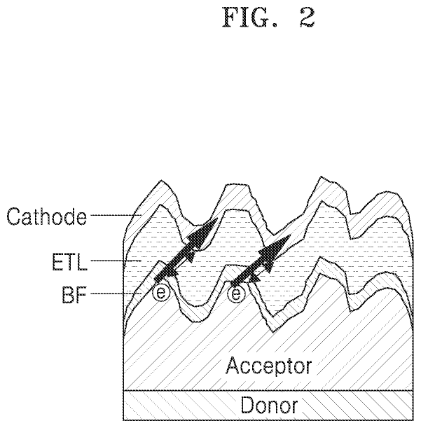

### [Descriptions of FIGS. 1 and 2]

FIG. 1 is a schematic cross-sectional view of an organic photodetector 10 included in an electronic apparatus according to an embodiment.

An electron transport region of the organic photodetector 10 may include a structure in which a buffer layer 150, a hole blocking layer (not shown), an electron transport layer 160, an electron injection layer (not shown), or any combination thereof are arranged on an activation layer 140. For example, the electron injection layer may be arranged between a second electrode 170 and the electron transport layer 160.

Referring to FIG. 1, the organic photodetector 10 included in the electronic apparatus according to an embodiment may include: a first electrode 110; the second electrode 170 facing the first electrode 110; the activation layer 140 arranged between the first electrode 110 and the second electrode 170; an electron injection layer (not shown) arranged between the activation layer 140 and the second electrode 170; the electron transport layer 160; the buffer layer 150; and a hole injection layer 120, a hole transport layer 131, and an optical auxiliary layer 132, which are arranged between the first electrode 110 and the activation layer 140.

The activation layer 140 may generate excitons by receiving light from the outside and divide the generated excitons into holes and electrons. The activation layer 140 may include a p-type semiconductor compound (donor compound) and an n-type semiconductor compound (acceptor compound).

The optical auxiliary layer 132 may increase light introduction efficiency by compensating for an optical resonance distance according to a wavelength of light introduced into the activation layer 140.

In FIG. 1, for example, in some cases, the electron injection layer (not shown), the buffer layer 150, and the hole injection layer 120 may each independently be present or absent.

The activation layer 140 may include a p-type semiconductor compound and an n-type semiconductor compound. For example, the activation layer 140 may be a mixed layer including a p-type semiconductor compound and an n-type semiconductor compound, or may include a layer including a p-type semiconductor compound (not shown) and a layer including an n-type semiconductor compound (not shown). When the activation layer 140 includes a layer including a p-type semiconductor compound (not shown) and a layer including an n-type semiconductor compound (not shown), the layer including the p-type semiconductor compound (not shown) and the layer including the n-type semiconductor compound (not shown) may be in direct contact with each other, the layer including the n-type semiconductor compound may face the second electrode 170, and the layer including the p-type semiconductor compound may face the first electrode 110. The layer including the p-type semiconductor compound and the layer including the n-type semiconductor compound may form a PN junction. Excitons may be efficiently separated into holes and electrons by photo-induced charge separation occurring at an interface between these layers.

When the activation layer 140 is a mixed layer, excitons may be generated within a diffusion length from a p-type semiconductor compound-n-type semiconductor compound interface, and thus, the organic photodetector may have improved efficiency. The ratio of the p-type semiconductor compound to the n-type semiconductor compound may be, for example, in a range of about 10:90 to about 90:10 (weight ratio).

In an embodiment, the activation layer may include a layer including an n-type semiconductor compound, and a lowest unoccupied molecular orbital (LUMO) energy value of the layer may be greater than −4.50 eV and less than −3.20 eV.

For example, the activation layer may include a layer consisting of an n-type semiconductor compound, and a LUMO energy value of the layer may be greater than −4.50 eV and less than −3.20 eV. When the LUMO energy value of the layer consisting of the n-type semiconductor compound in the activation layer is within the above range, the organic photodetector may have excellent efficiency.

In an embodiment, the activation layer may include a layer including a p-type semiconductor compound and a layer including an n-type semiconductor compound, the layer including the n-type semiconductor compound may be in contact with the electron transport region arranged between the first pixel electrode and the counter electrode, and a difference between a LUMO energy value of a layer in the electron transport region in contact with the layer including the n-type semiconductor compound and a LUMO energy value of the layer including the n-type semiconductor compound may be 0.3 eV or more.

For example, the LUMO energy value of the layer in the electron transport region in contact with the layer including the n-type semiconductor compound may be greater than the LUMO energy value of the layer including the n-type semiconductor compound.

For example, the layer in the electron transport region in contact with the layer including the n-type semiconductor compound may be a buffer layer or an electron transport layer.

When a difference between the LUMO energy value of the layer (e.g., a buffer layer or an electron transport layer) in the electron transport region in contact with the layer including the n-type semiconductor compound and the LUMO energy value of the layer including the n-type semiconductor compound is 0.3 eV or more, tunneling of electrons may occur. In this case, the layer in the electron transport region (e.g., a buffer layer or an electron transport layer) in contact with the layer including the n-type semiconductor compound has a mean square roughness (R_{q}) value of 9 nm and has an uneven surface, in accordance with this disclosure. When the layer has a mean square roughness (R_{q}) value less than 5 nm and so has a smooth surface, it may be difficult for tunneling of electrons to occur. As used herein, “rough” or “uneven” indicates the presence or more texture on a surface than “smooth.”

In an embodiment, the activation layer 140 may be a mixed layer consisting of a p-type semiconductor compound and an n-type semiconductor compound. For example, the activation layer 140 may consist of a layer consisting of a p-type semiconductor compound and a layer consisting of an n-type semiconductor compound.

In an embodiment, the p-type semiconductor compound may include a compound represented by Formula 1:

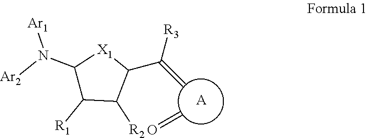

wherein, in Formula 1,
X₁ may be O, S, Se, Te, SO, SO₂, CR₁₁R₁₂, or SiR₁₃R₁₄,
A may be a C₃-C₆₀ carbocyclic group unsubstituted or substituted with at least one R₁₀ₐ or a C₁-C₆₀ heterocyclic group unsubstituted or substituted with at least one R₁₀ₐ,
R₁, R2, and R₃, R₁₁, R₁₂, R₁₃, and R₁₄, Ar₁, and Ar₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₂ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof, and
neighboring substituents among R₁, R₂, and R₃, R₁₁, R₁₂, R₁₃, and R₁₄, Ar₁, and Ar₂ may optionally be bonded to each other to form a ring.

In an embodiment, the p-type semiconductor compound may include one of compounds below:

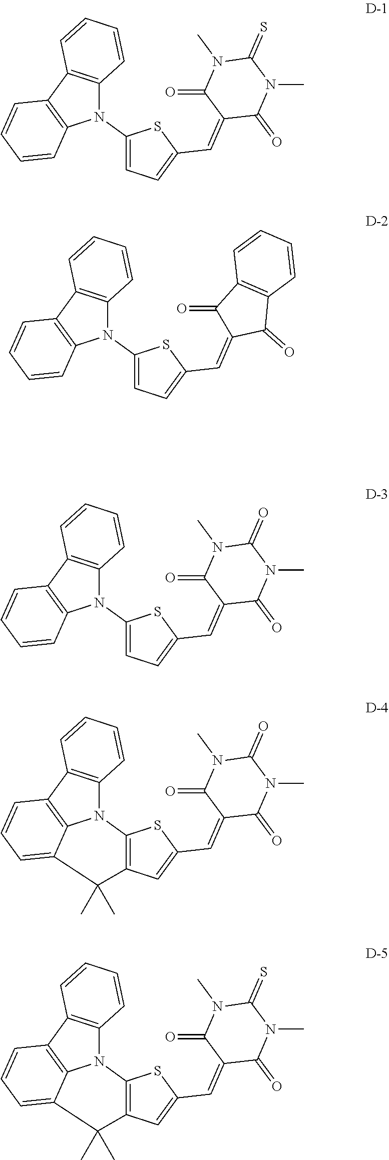 [SMILES: CN1C(=O)C(=Cc2ccc(-n3c4ccccc4c4ccccc43)s2)C(=O)N(C)C1=S ; O=C1C(=Cc2ccc(-n3c4ccccc4c4ccccc43)s2)C(=O)c2ccccc21 ; CN1C(=O)C(=Cc2ccc(-n3c4ccccc4c4ccccc43)s2)C(=O)N(C)C1=O ; CN1C(=O)C(=Cc2cc3c(s2)-n2c4ccccc4c4cccc(c42)C3(C)C)C(=O)N(C)C1=O ; CN1C(=O)C(=Cc2cc3c(s2)-n2c4ccccc4c4cccc(c42)C3(C)C)C(=O)N(C)C1=S]

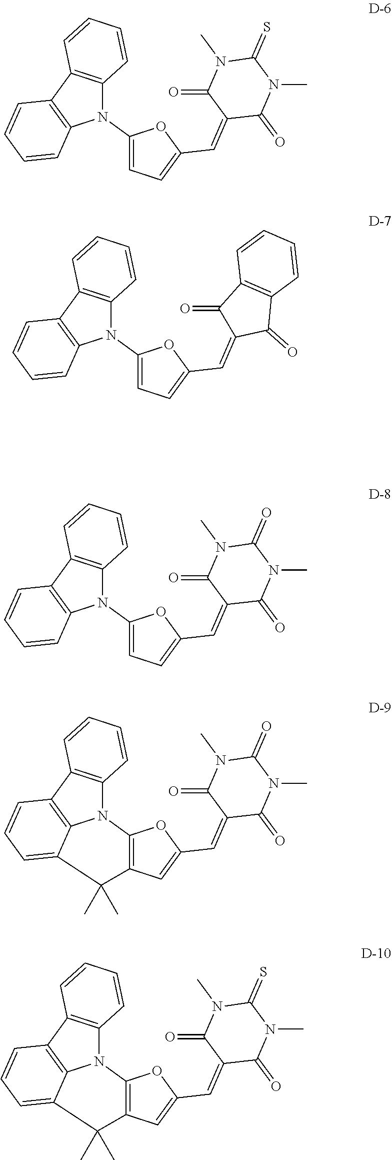 [SMILES: CN1C(=O)C(=Cc2ccc(-n3c4ccccc4c4ccccc43)o2)C(=O)N(C)C1=S ; O=C1C(=Cc2ccc(-n3c4ccccc4c4ccccc43)o2)C(=O)c2ccccc21 ; CN1C(=O)C(=Cc2ccc(-n3c4ccccc4c4ccccc43)o2)C(=O)N(C)C1=O ; CN1C(=O)C(=Cc2cc3c(o2)-n2c4ccccc4c4cccc(c42)C3(C)C)C(=O)N(C)C1=O ; CN1C(=O)C(=Cc2cc3c(o2)-n2c4ccccc4c4cccc(c42)C3(C)C)C(=O)N(C)C1=S]

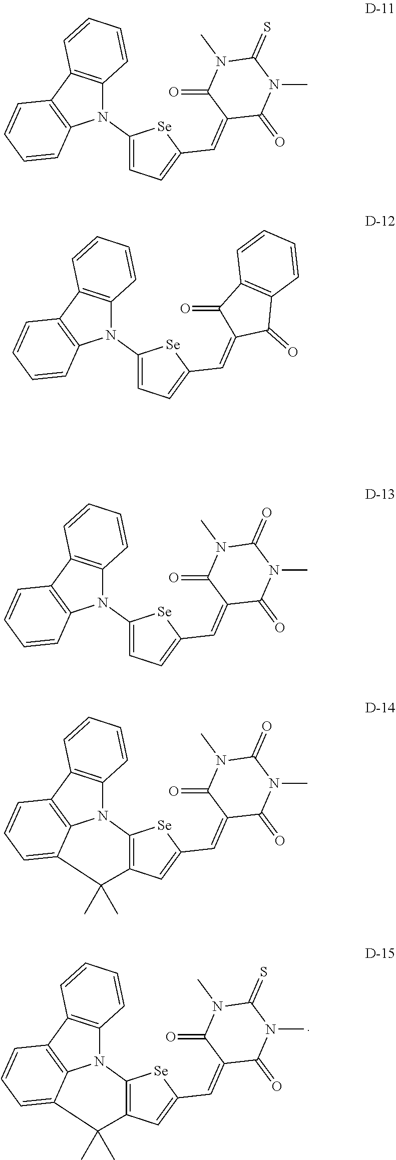 [SMILES: CN1C(=O)C(=Cc2ccc(-n3c4ccccc4c4ccccc43)[se]2)C(=O)N(C)C1=S ; O=C1C(=Cc2ccc(-n3c4ccccc4c4ccccc43)[se]2)C(=O)c2ccccc21 ; CN1C(=O)C(=Cc2ccc(-n3c4ccccc4c4ccccc43)[se]2)C(=O)N(C)C1=O ; CN1C(=O)C(=Cc2cc3c([se]2)-n2c4ccccc4c4cccc(c42)C3(C)C)C(=O)N(C)C1=O ; CN1C(=O)C(=Cc2cc3c([se]2)-n2c4ccccc4c4cccc(c42)C3(C)C)C(=O)N(C)C1=S]

In an embodiment, the n-type semiconductor compound may include a compound represented by Formula 2 or 3:

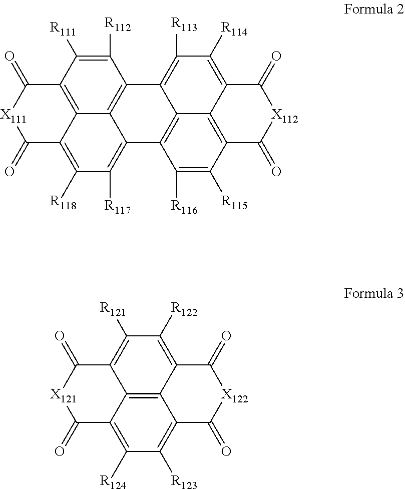

wherein, in Formula 2,
X₁₁₁ and X₁₁₂ may each independently be O or NR₁₁₉, and
R₁₁₁, R₁₁₂, R₁₁₃, R₁₁₄, R₁₁₅, R₁₁₆, R₁₁₇, R₁₁₈, and R₁₁₉ may each independently be hydrogen, deuterium, a halogen, a cyano group, a nitro group, a hydroxy group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or any combination thereof, wherein, in Formula 3,
X₁₂₁ and X₁₂₂ may each independently be O or NR₁₂₅, and
R₁₂₁, R₁₂₂, R₁₂₃, R₁₂₄, and R₁₂₅ may each independently be hydrogen, deuterium, a halogen, a cyano group, a nitro group, a hydroxy group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or any combination thereof,
wherein, in Formulae 2 and 3,
R₁₀ₐ may be:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁, Q₁₂, and Q₁₃, Q₂₁, Q₂₂, and Q₂₃, and Q₃₁ and Q₃₂ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, the n-type semiconductor compound may include one of compounds below:

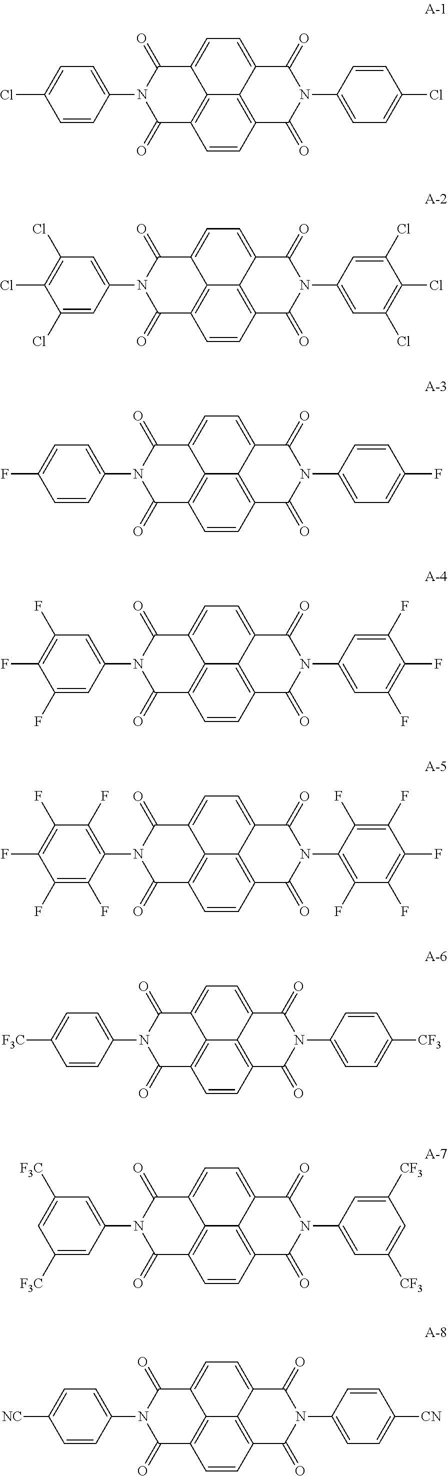

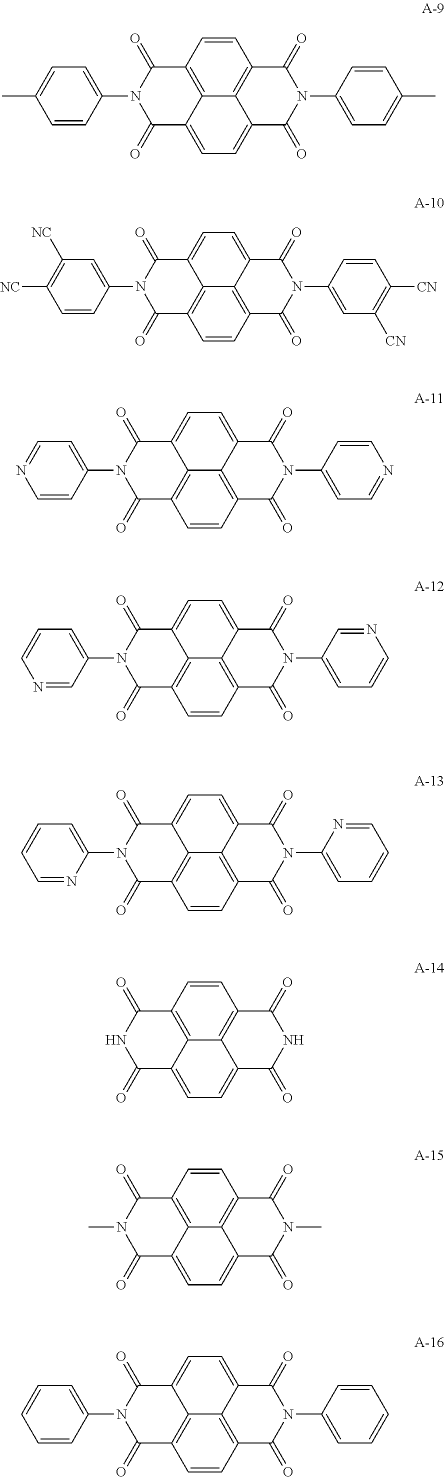

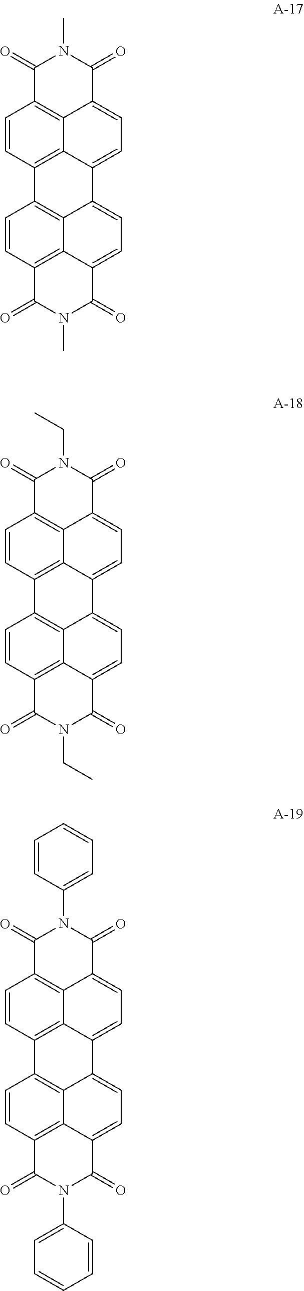 [SMILES: CN1C(=O)c2ccc3c4ccc5c6c(ccc(c7ccc(c2c37)C1=O)c64)C(=O)N(C)C5=O ; CCN1C(=O)c2ccc3c4ccc5c6c(ccc(c7ccc(c2c37)C1=O)c64)C(=O)N(CC)C5=O ; O=C1c2ccc3c4ccc5c6c(ccc(c7ccc(c2c37)C(=O)N1c1ccccc1)c64)C(=O)N(c1ccccc1)C5=O]

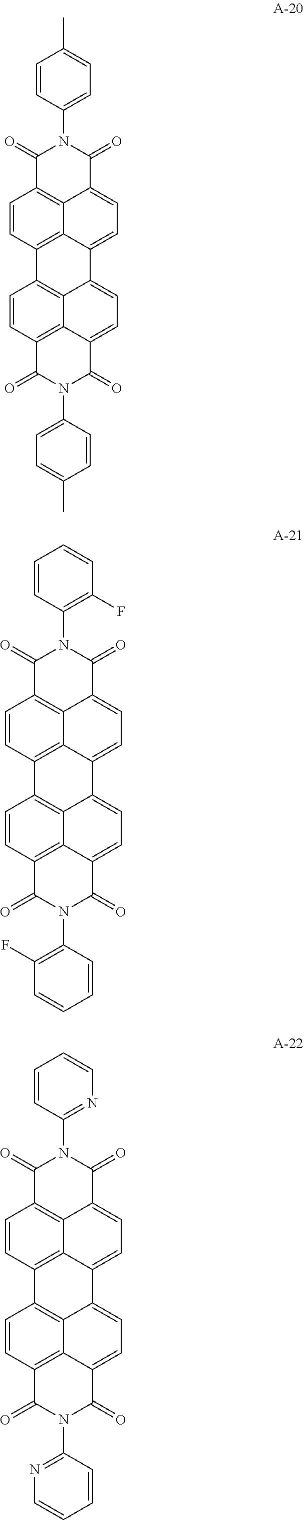

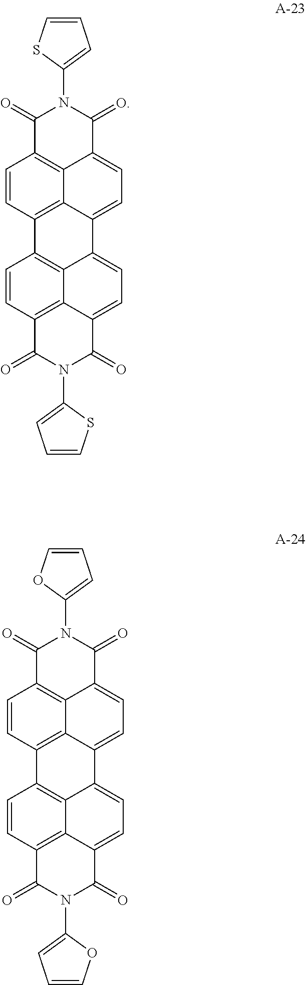 [SMILES: O=C1c2ccc3c4ccc5c6c(ccc(c7ccc(c2c37)C(=O)N1c1cccs1)c64)C(=O)N(c1cccs1)C5=O ; O=C1c2ccc3c4ccc5c6c(ccc(c7ccc(c2c37)C(=O)N1c1ccco1)c64)C(=O)N(c1ccco1)C5=O]

The overall thickness of the activation layer 140 may be in a range of about 200 Å to about 2,000 Å, for example, about 400 Å to about 600 Å. When the activation layer 140 includes a layer including a p-type semiconductor compound and a layer including an n-type semiconductor compound, the thicknesses of the layer including the p-type semiconductor compound and the layer including the n-type semiconductor compound may independently be in a range of about 50 Å to about 1,000 Å, for example, about 100 Å to about 400 Å.

When the thickness of the activation layer 140 is within the above range, incident light absorption may be efficient.

One of the first electrode 110 and the second electrode 170 may be an anode, and the other one may be a cathode. For example, the first electrode 110 may be an anode, and the second electrode 170 may be a cathode.

A hole transport region of the organic photodetector 10 may include a structure in which the hole injection layer 120, the hole transport layer 131, an electron blocking layer (not shown), the optical auxiliary layer 132, or any combination thereof are arranged on the first electrode 110. For example, the hole injection layer 120 may be arranged between the first electrode 110 and the hole transport layer 131.

For example, the hole transport layer 131 may include a layer including a p-dopant (not shown). The layer including the p-dopant may be in direct contact with the first electrode 110.

The p-dopant will be described below.

In an embodiment, the electron transport region and the activation layer of the organic photodetector may be in contact with each other, and a mean square roughness (R_{q}) value of a surface of the activation layer in a direction of contact with the electron transport region may be 9 nm or more.

For example, the layer including the n-type semiconductor compound (acceptor compound) may be in contact with the electron transport region.

For example, one layer of the electron transport region may be in contact with the activation layer. In this case, for example, the activation layer may be a mixed layer consisting of a p-type semiconductor compound and an n-type semiconductor compound.

For example, a mean square roughness (R_{q}) value of a surface of each layer of the electron transport region may be 9 nm or more. For example, mean square roughness (R_{q}) values of surfaces of “all” layers of the electron transport region may each be 9 nm or more.

For example, mean square roughness (R_{q}) values of both surfaces of the counter electrode (e.g., a cathode) facing the first pixel electrode (e.g., an anode) may each be 9 nm or more. That is, a mean square roughness (R_{q}) value of a surface of the counter electrode facing the first pixel electrode and a mean square roughness (R_{q}) value of a surface of the counter electrode facing away from the first pixel electrode may each be 9 nm or more.

On the other hand, when the activation layer includes a layer including a p-type semiconductor compound (donor compound) and a layer including an n-type semiconductor compound (acceptor compound), the layer including the p-type semiconductor compound and the layer including the n-type semiconductor compound are in direct contact with each other.

A mean square roughness (R_{q}) value of a surface of the layer including the p-type semiconductor compound in contact with the layer including the n-type semiconductor compound may be less than 5 nm.

When a mean square roughness (R_{q}) value of a surface is 9 nm or more, the surface may be characterized as rough or uneven. When a mean square roughness (R_{q}) value of a surface is less than 5 nm, the surface may be characterized as smooth.

That is, in the organic photodetector 10 included in the electronic apparatus according to an embodiment, all surfaces from the point where the mixed layer is in contact with the electron transport region to the second electrode may have a mean square roughness (R_{q}) value of 9 nm or more.

For example, a mean square roughness (R_{q}) value of a rough surface may be in a range of about 9 nm to about 20 nm. A mean square roughness (R_{q}) value of a smooth surface may be greater than 0 nm and less than 5 nm.

FIG. 2 is a schematic enlarged view of an oval portion in FIG. 1.

Referring to FIG. 2, the activation layer 140 may include a layer including a p-type semiconductor compound (donor compound) and a layer including an n-type semiconductor compound (acceptor compound), a mean square roughness (R_{q}) value of a surface of the layer including the n-type semiconductor compound (acceptor compound) in contact with a buffer layer BF may be 9 nm or more.

Referring to FIG. 2, mean square roughness (R_{q}) value of surfaces of all layers included in the electron transport region, such as the buffer layer BF and an electron transport layer ETL, may each be 9 nm or more.

Referring to FIG. 2, a mean square roughness (R_{q}) value of a surface of the layer including the p-type semiconductor compound (donor compound) in contact with the layer including the n-type semiconductor compound (acceptor compound) may be less than 5 nm.

Referring to FIG. 2, mean square roughness (R_{q}) values of both surfaces of a counter electrode (cathode) may each be 9 nm or more.

Referring to FIG. 2, it may be seen that a distance (↔) from the surface of the layer including the n-type semiconductor compound (acceptor compound) to the counter electrode (cathode) may be substantially reduced, thereby facilitating tunneling (→) of electrons.

### [First Electrode 110]

In FIG. 1, a substrate may be additionally arranged under the first electrode 110 or on the second electrode 170. In an embodiment, as the substrate, a glass substrate or a plastic substrate may be used. In one or more embodiments, the substrate may be a flexible substrate, and may include plastics with excellent heat resistance and durability, such as polyimide, polyethylene terephthalate (PET), polycarbonate, polyethylene napthalate, polyarylate (PAR), polyetherimide, or any combination thereof.

The first electrode 110 may be formed by, for example, depositing or sputtering a material for forming the first electrode 110 on the substrate. When the first electrode 110 is an anode, a high-work function material may be used as a material for forming the first electrode 110.

The first electrode 110 may be a reflective electrode, a semi-transmissive electrode, or a transmissive electrode. In an embodiment, when the first electrode 110 is a transmissive electrode, indium tin oxide (ITO), indium zinc oxide (IZO), tin oxide (SnO₂), zinc oxide (ZnO), or any combination thereof may be used as a material for forming the first electrode 110. In one or more embodiments, when the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be used as a material for forming the first electrode 110.

The first electrode 110 may have a single-layer structure consisting of a single layer or a multi-layer structure including multiple layers. For example, the first electrode 110 may have a three-layer structure of ITO/Ag/ITO.

### [Charge Auxiliary Layer]

The organic photodetector 10 according to an embodiment may include a charge auxiliary layer that facilitates migration of holes and electrons from the activation layer 140.

The charge auxiliary layer may include the hole injection layer 120 and the hole transport layer 131, which facilitate migration of holes, and may include the electron transport layer 160 and an electron injection layer (not shown), which facilitate migration of electrons.

### [Hole Transport Region]

Charge auxiliary layers arranged between the first electrode 110 and the activation layer 140 may be collectively referred to as a hole transport region.

The hole transport region may include the hole injection layer 120, the hole transport layer 131, and an electron blocking layer.

The hole transport region may include a hole transport material. For example, the hole transport material may include a compound represented by Formula 201, a compound represented by Formula 202, or any combination thereof:

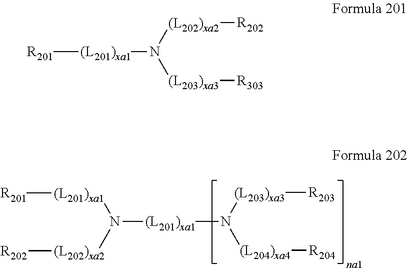

wherein, in Formulae 201 and 202,
L₂₀₁, L₂₀₂, L₂₀₃, and L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₅-C₆₀ carbocyclic group unsubstituted or substituted with at least one R₁₀ₐ, or a C₁-C₆₀ heterocyclic group unsubstituted or substituted with at least one R₁₀ₐ,
xa1, xa2, xa3, and xa4 may each independently be an integer from 0 to 5,
xa5 may be an integer from 1 to 10,
R₂₀₁, R₂₀₂, R₂₀₃, and R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (e.g., a carbazole group, etc.) unsubstituted or substituted with at least one R₁₀ₐ (e.g., Compound HT16, etc.),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and
na1 may be an integer from 1 to 4.

For example, each of Formulae 201 and 202 may include at least one of groups represented by Formulae CY201 to CY217:

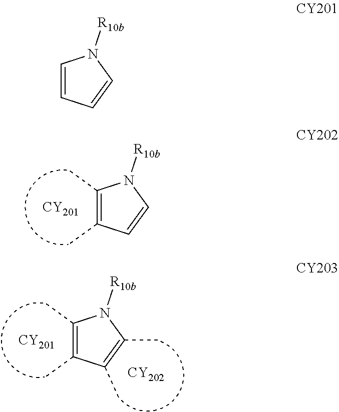

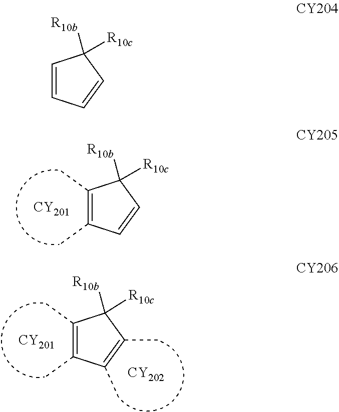

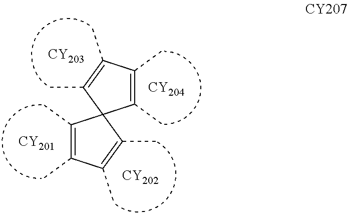

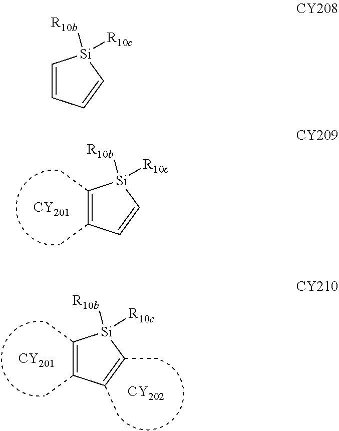

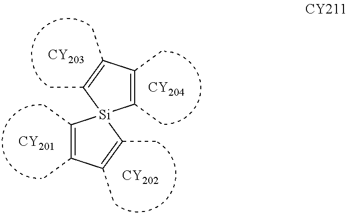

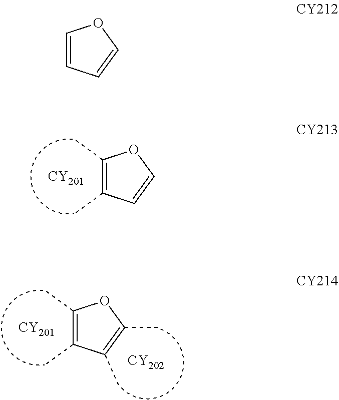

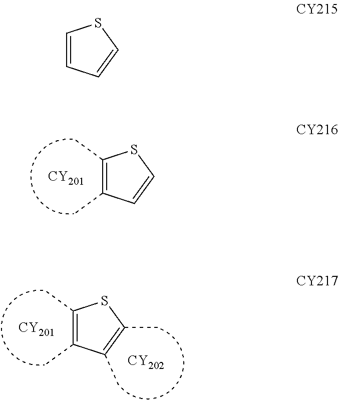

wherein, in Formulae CY201 to CY217, R_{10b} and R_{10c} may each be the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, in Formulae CY201 to CY217, ring CY201 to ring CY204 may each independently be a benzene group, a naphthalene group, a phenanthrene group, or an anthracene group.

In one or more embodiments, each of Formulae 201 and 202 may include at least one of the groups represented by Formulae CY201 to CY203.

In one or more embodiments, Formula 201 may include at least one of the groups represented by Formulae CY201 to CY203 and at least one of the groups represented by Formulae CY204 to CY217.

In one or more embodiments, in Formula 201, xa1 may be 1, R₂₀₁ may be one of the groups represented by Formulae CY201 to CY203, xa2 may be 0, and R₂₀₂ may be one of the groups represented by Formulae CY204 to CY207.

In one or more embodiments, each of Formulae 201 and 202 may not include the groups represented by Formulae CY201 to CY203.

In one or more embodiments, each of Formulae 201 and 202 may not include the groups represented by Formulae CY201 to CY203, and may include at least one of the groups represented by Formulae CY204 to CY217.

In one or more embodiments, each of Formulae 201 and 202 may not include the groups represented by Formulae CY201 to CY217.

For example, the hole transport material may include: one of Compounds HT1 to HT46; m-MTDATA; TDATA; 2-TNATA; NPB(NPD); β-NPB; TPD; spiro-TPD; spiro-NPB; methylated NPB; TAPC; HMTPD; 4,4′,4″-tris(N-carbazolyl)triphenylamine (TCTA); polyaniline/dodecylbenzenesulfonic acid (PANI/DBSA); poly(3,4-ethylenedioxythiophene)/poly(4-styrenesulfonate) (PEDOT/PSS); polyaniline/camphor sulfonic acid (PANI/CSA); polyaniline/poly(4-styrenesulfonate) (PANI/PSS); or any combination thereof:

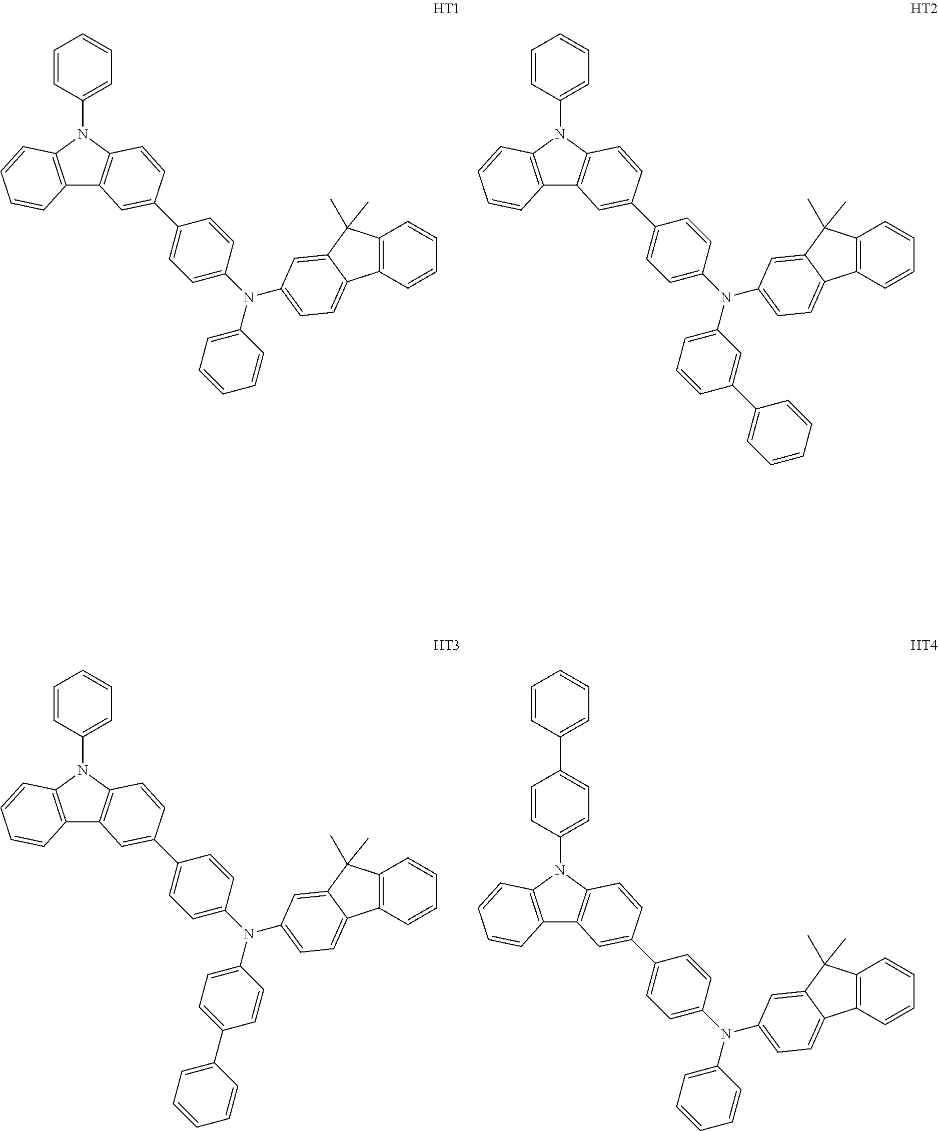

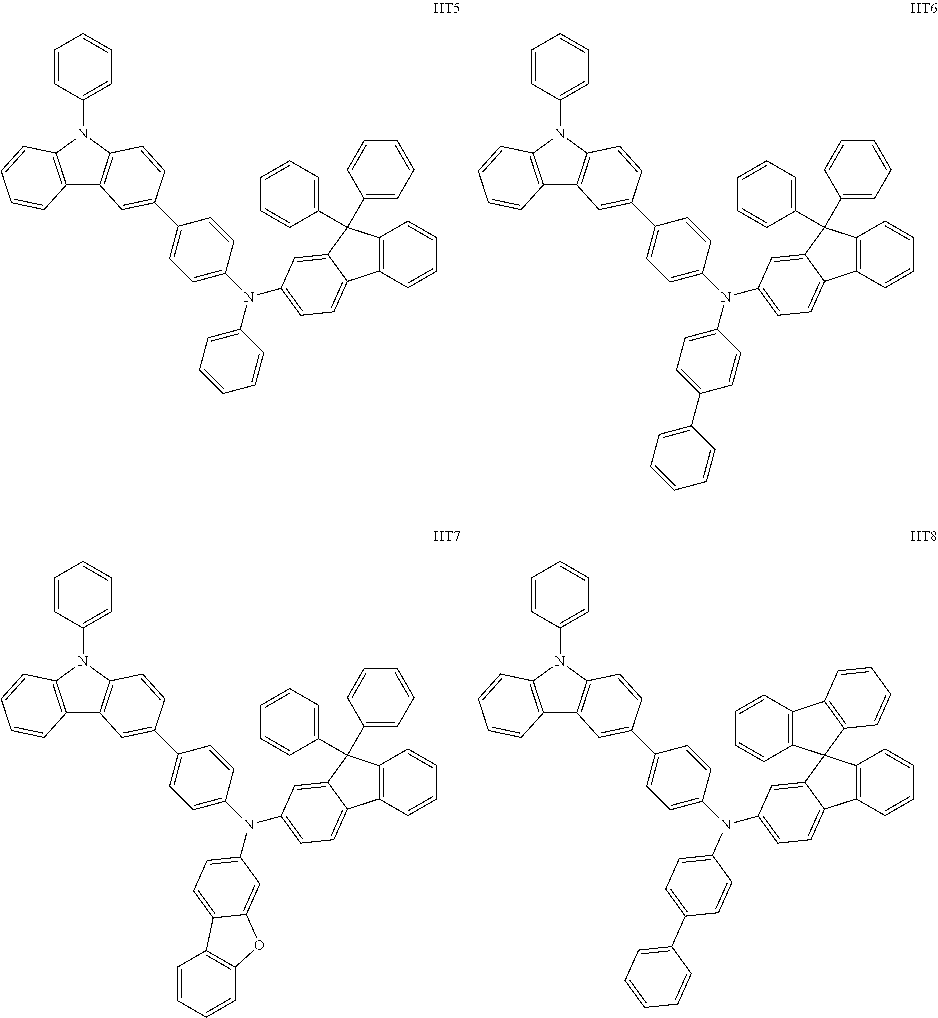 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

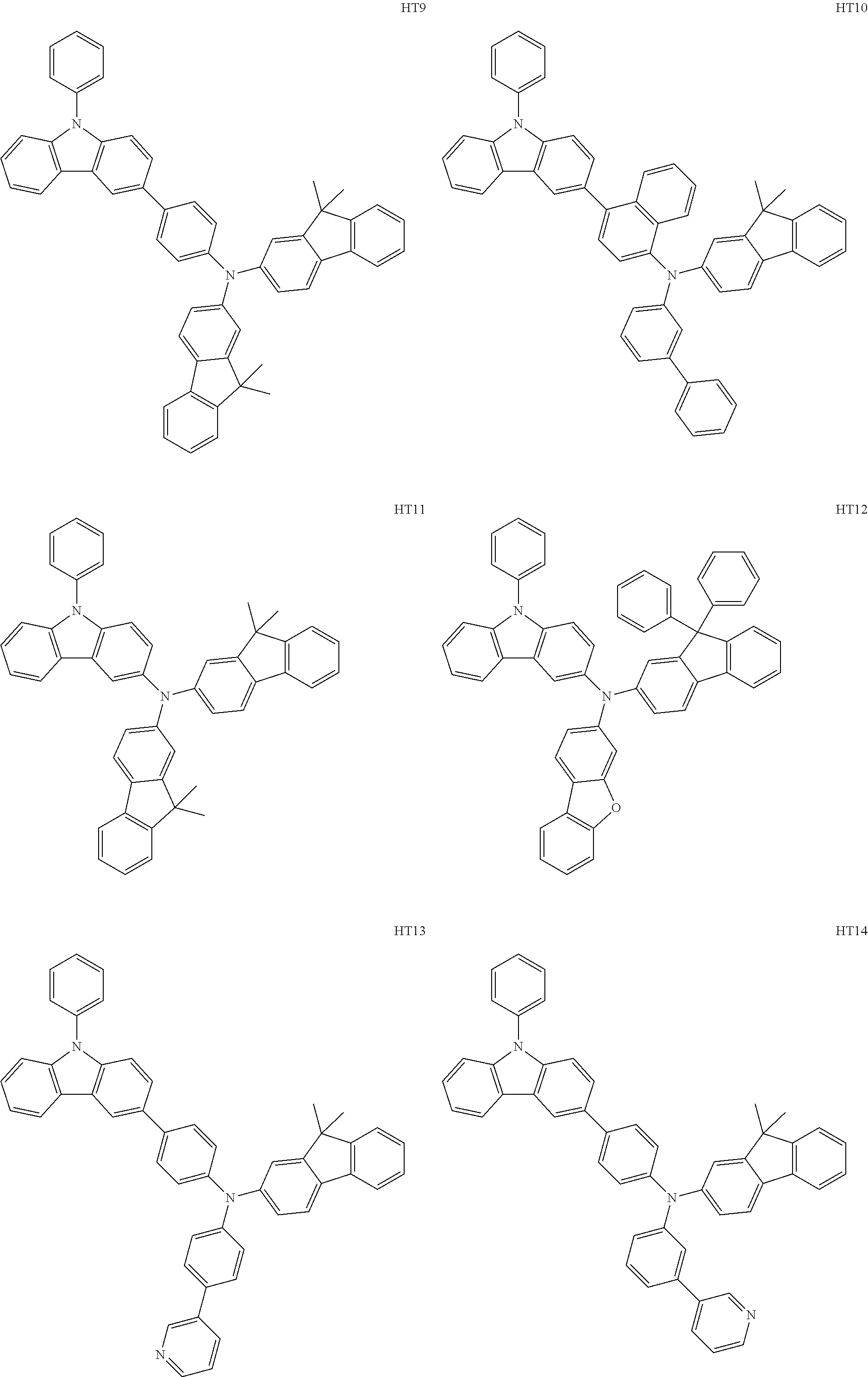

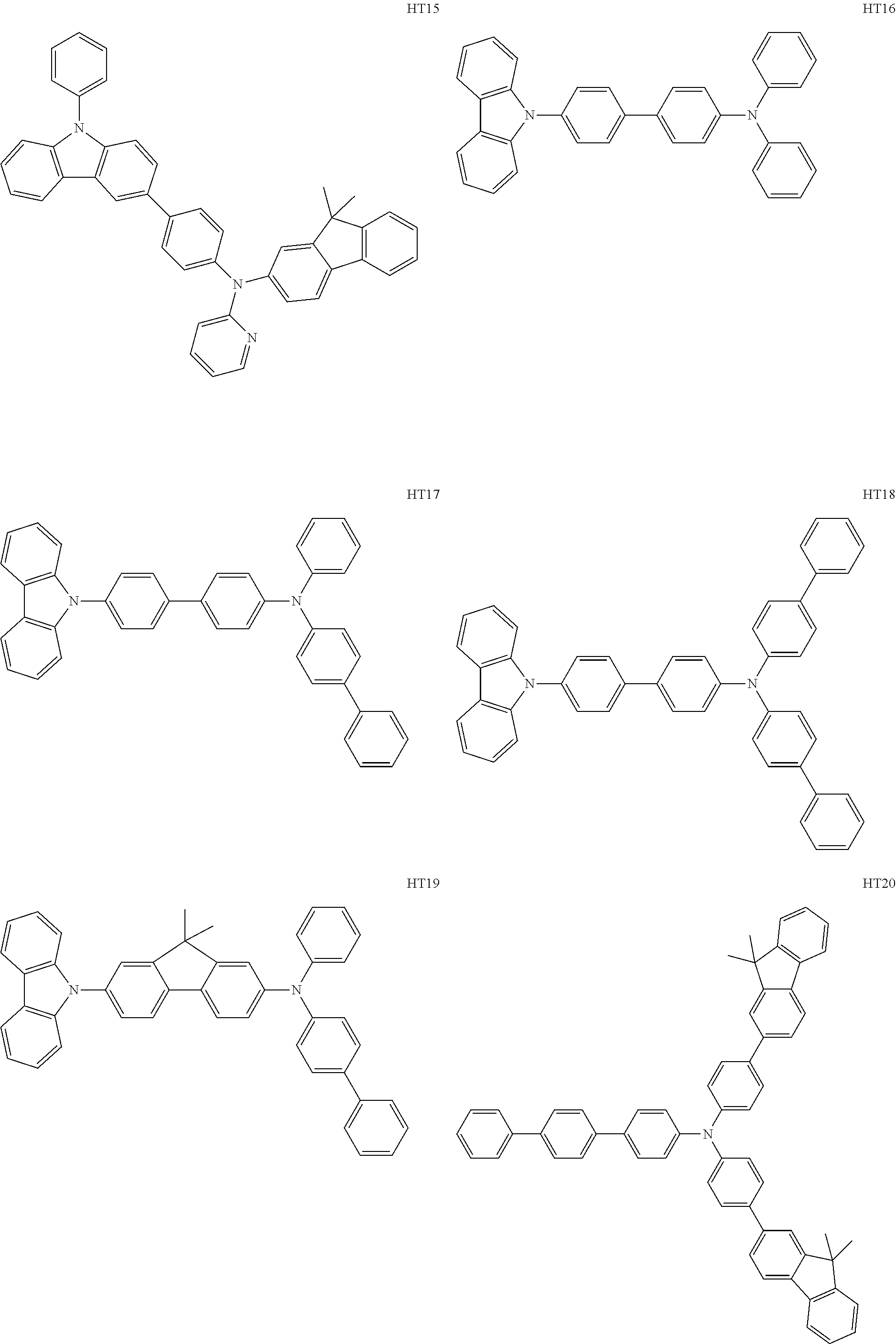 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

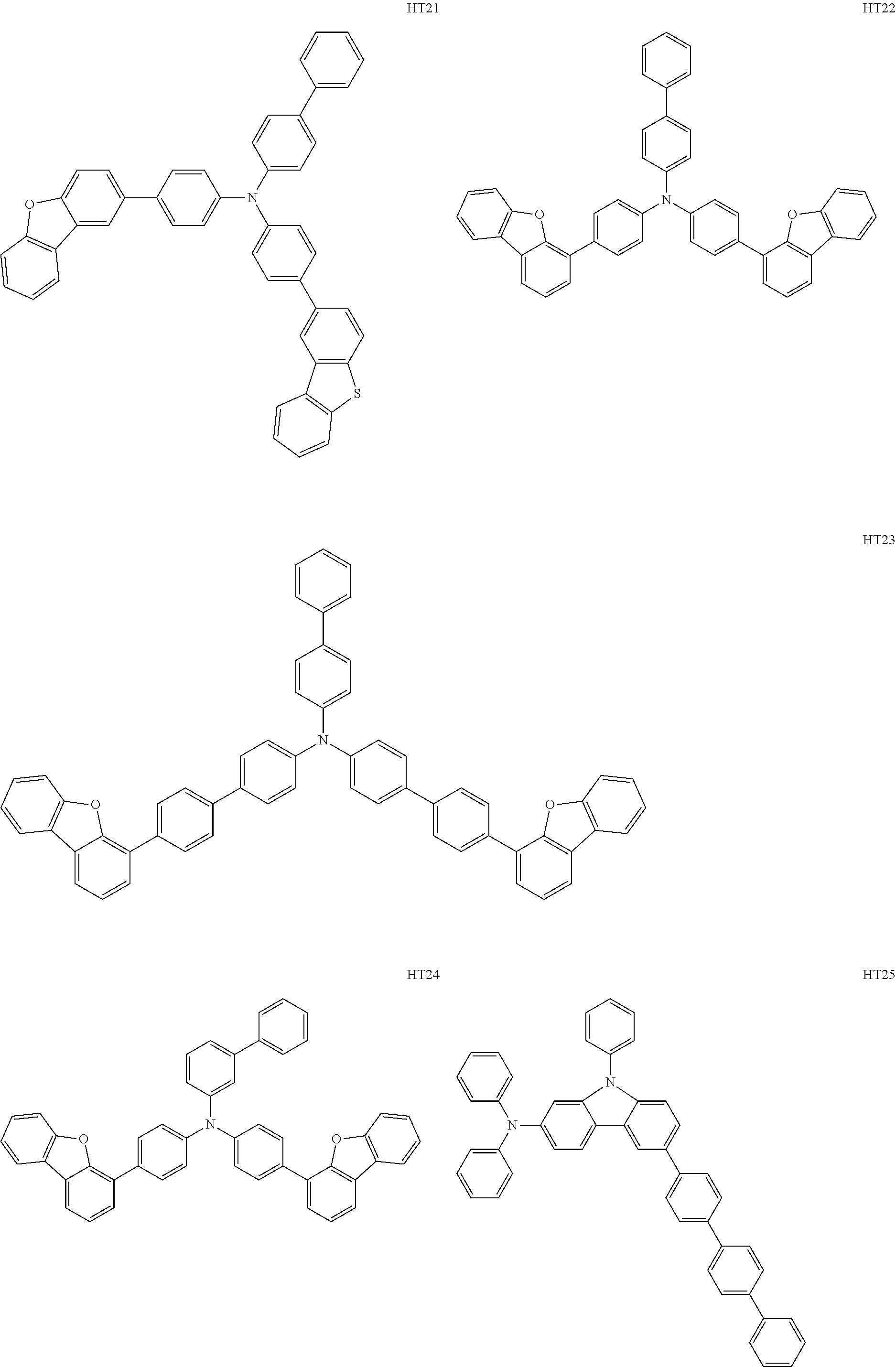 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1]

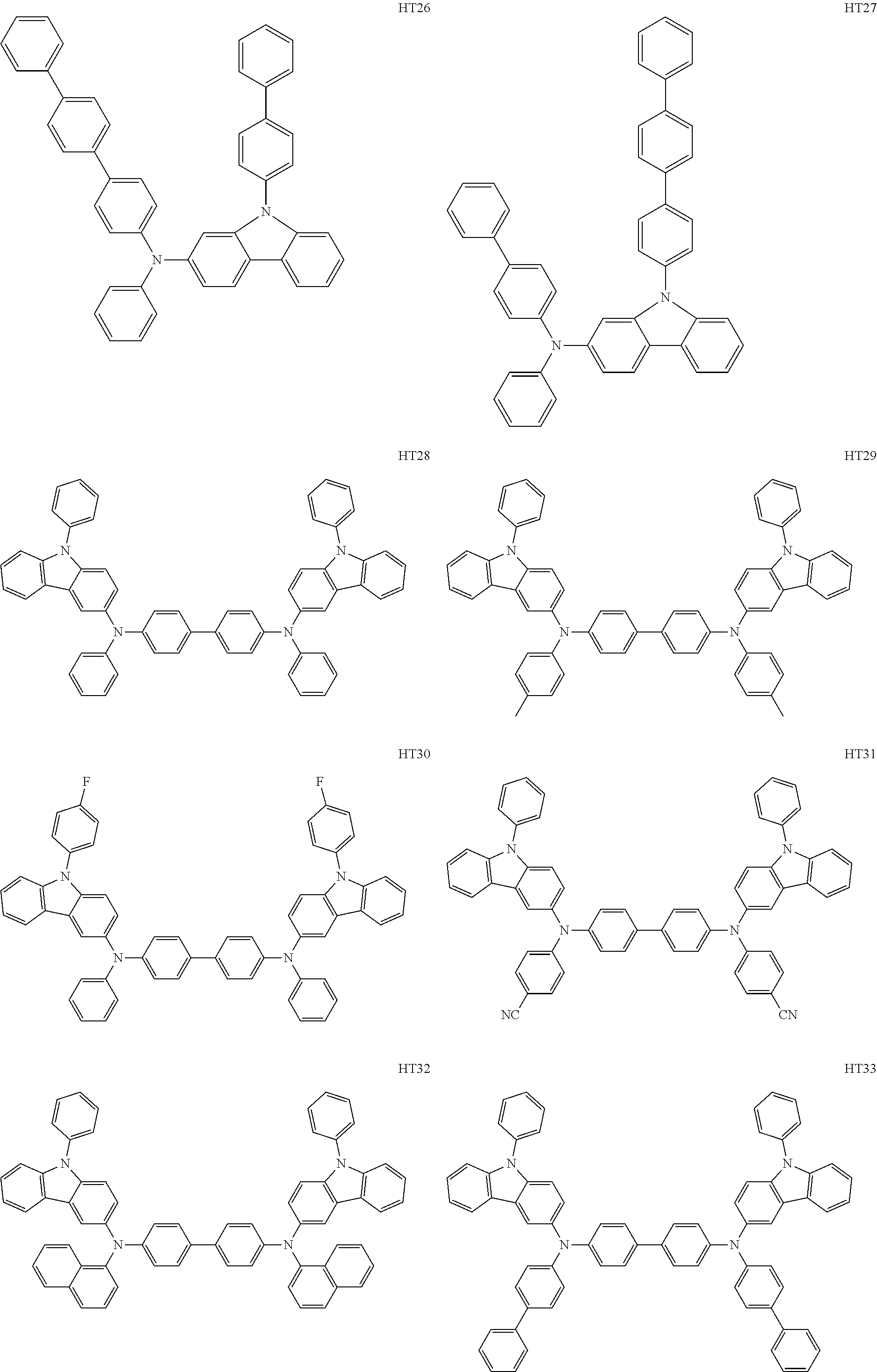

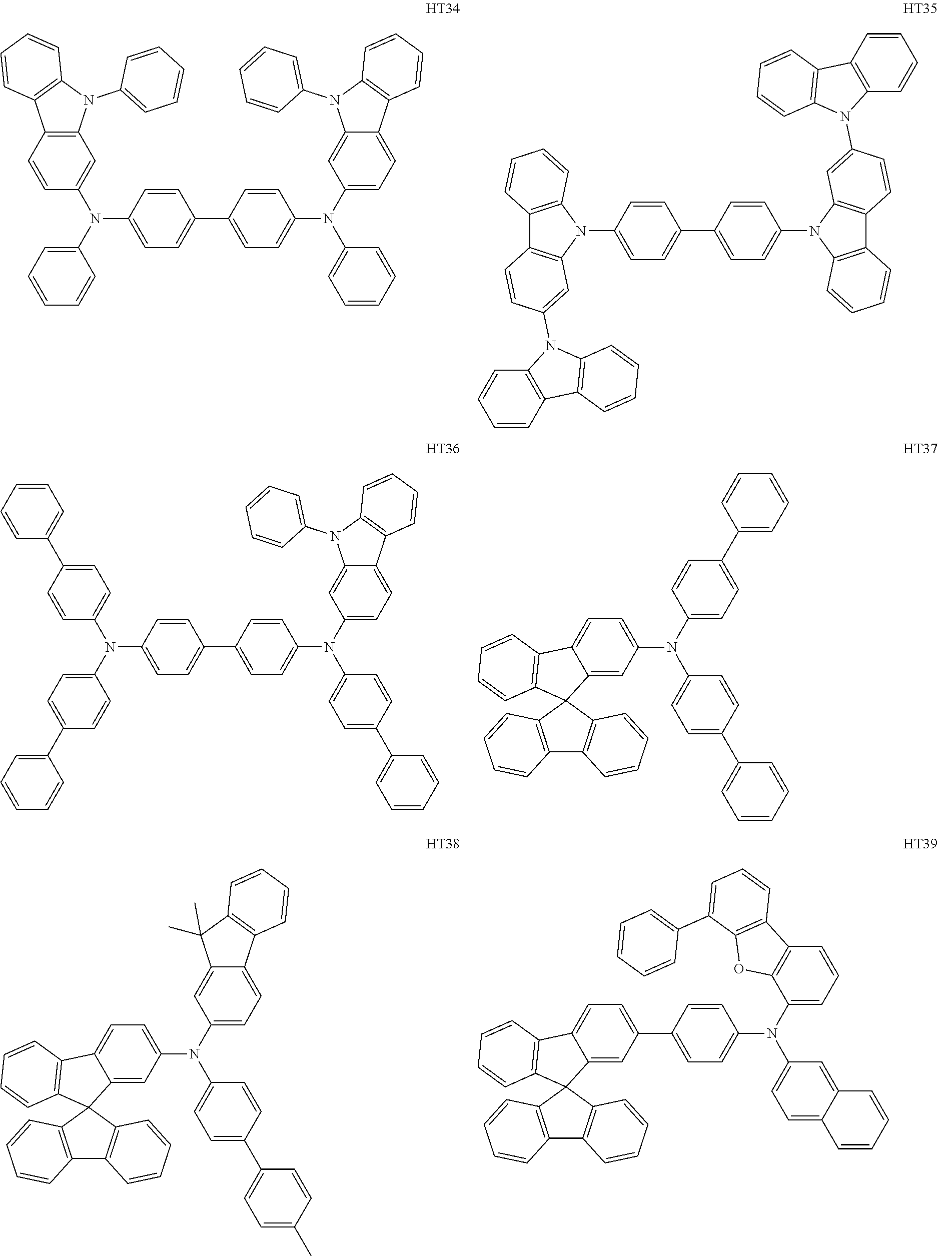

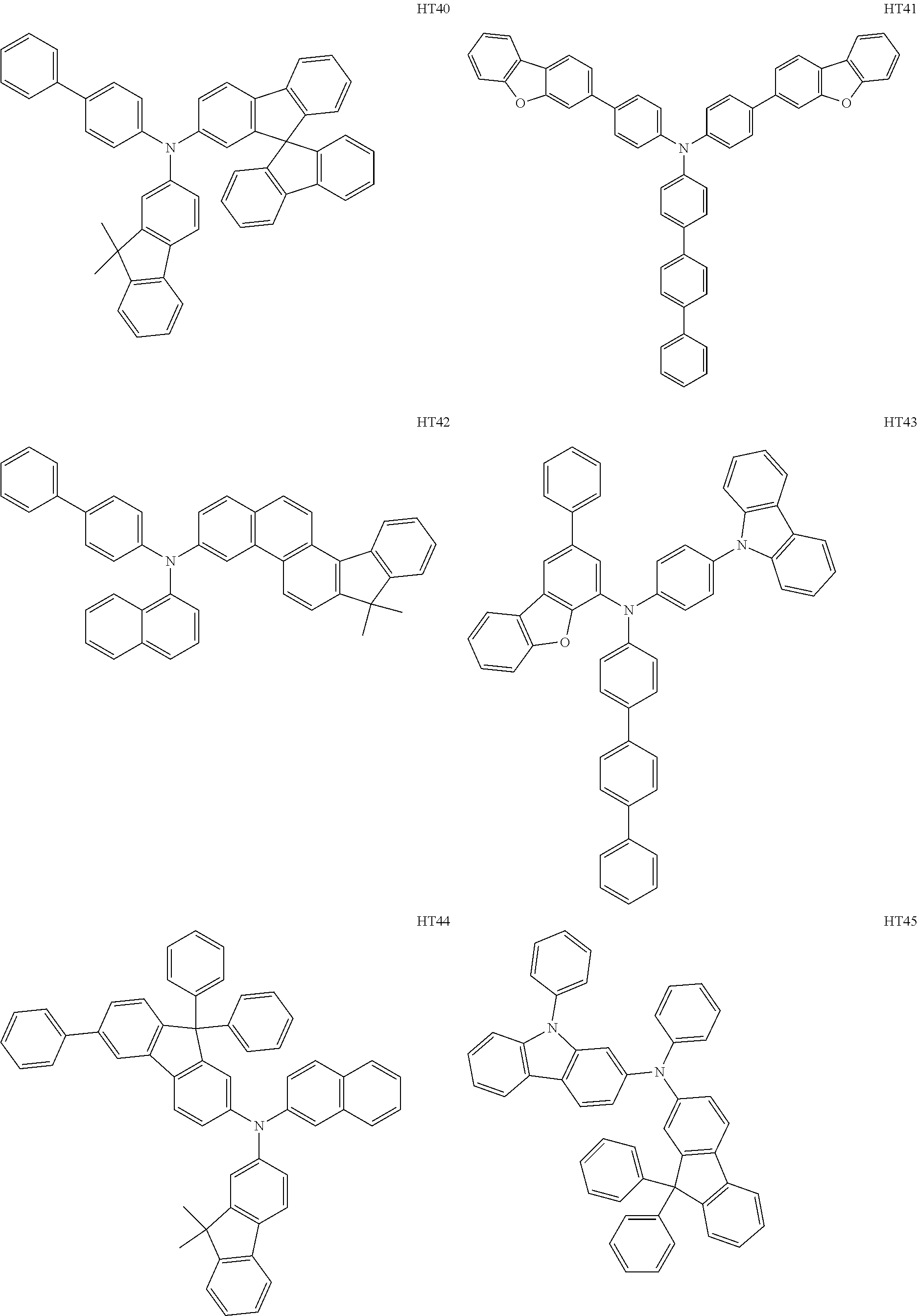

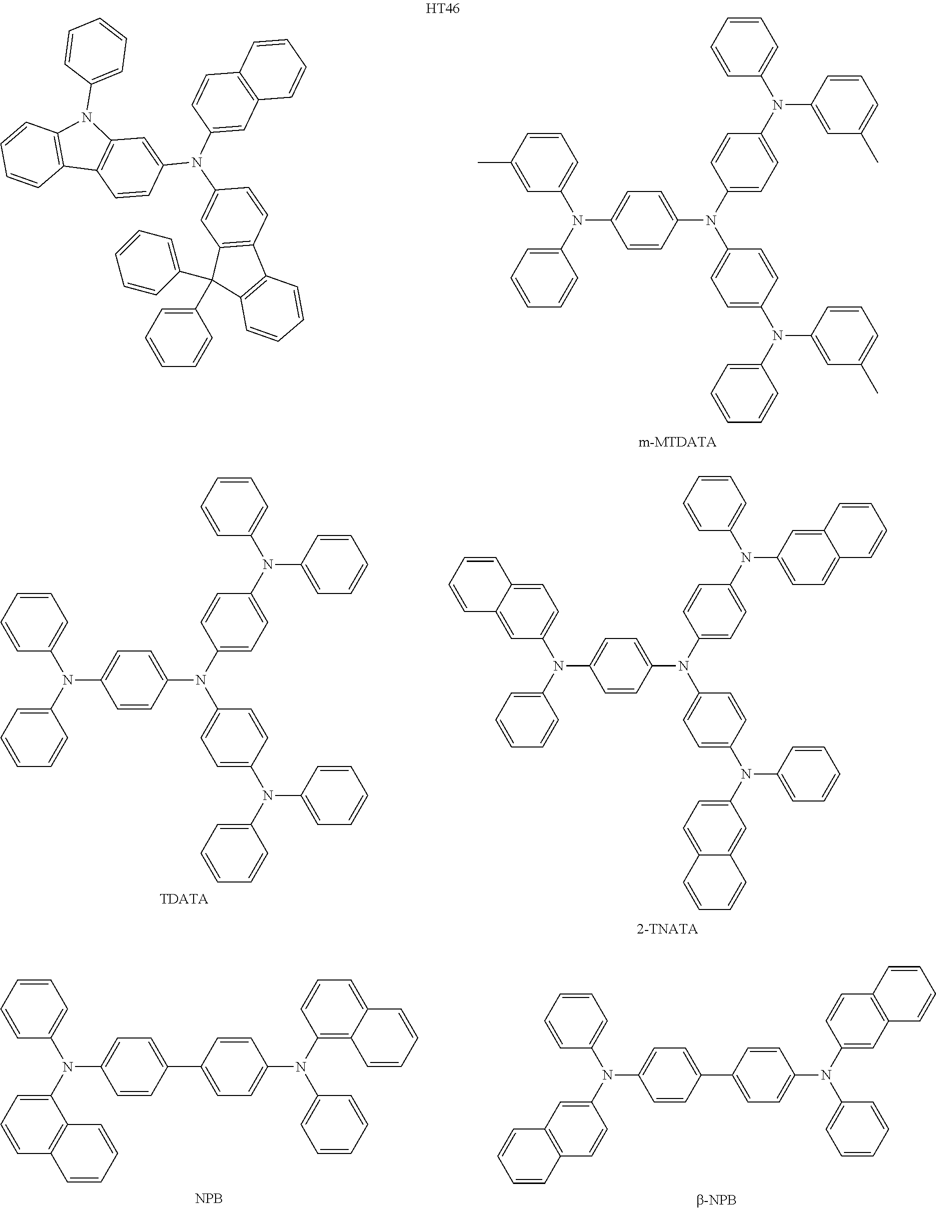

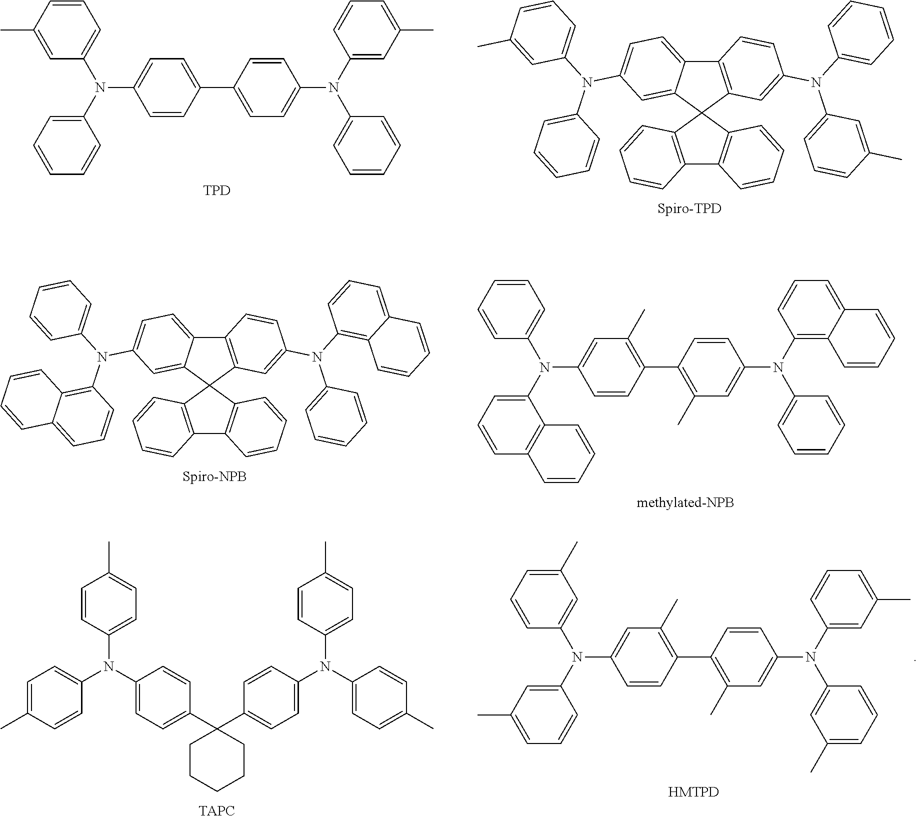

The thickness of the hole transport region may be in a range of about 50 Å to about 10,000 Å, for example, about 100 Å to about 4,000 Å. When the hole transport region includes a hole injection layer, a hole transport layer, or any combination thereof, the thickness of the hole injection layer may be in a range of about 100 Å to about 9,000 Å, for example, about 100 Å to about 1,000 Å, and the thickness of the hole transport layer may be in a range of about 50 Å to about 2,000 Å, for example, about 100 Å to about 1,500 Å. When the thicknesses of the hole transport region, the hole injection layer, and the hole transport layer are within the above-described ranges, satisfactory hole transporting characteristics may be obtained without a substantial increase in driving voltage.

The electron blocking layer may prevent leakage of electrons from the activation layer 140 into the hole transport region. The above-described hole transport material may be included in the electron transport layer and the electron blocking layer.

[p-dopant]

The hole transport region may further include, in addition to the above-described materials, a charge-generation material for the improvement of conductive properties. The charge-generation material may be uniformly or non-uniformly dispersed in the hole transport region (e.g., in the form of a single layer consisting of a charge-generation material).

The charge-generation material may be, for example, a p-dopant.

For example, a LUMO energy level of the p-dopant may be −3.5 eV or less.

In an embodiment, the p-dopant may include a quinone derivative, a cyano group-containing compound, a compound including element EL1 and element EL2, or any combination thereof.

Examples of the quinone derivative are TCNQ, F4-TCNQ, and the like.

Examples of the cyano group-containing compound are HAT-CN, a compound represented by Formula 221, and the like:

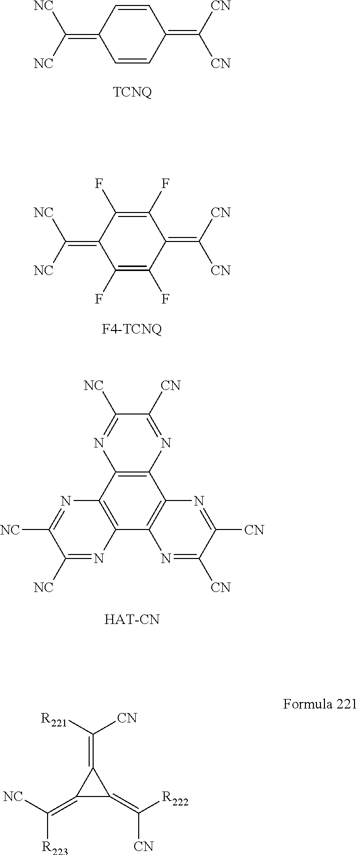

wherein, in Formula 221,
R₂₂₁, R₂₂₂, and R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
at least one of R₂₂₁, R₂₂₂, and R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be metal, metalloid, or any combination thereof, and element EL2 may be non-metal, metalloid, or any combination thereof.

Examples of the metal are an alkali metal (e.g., lithium (Li), sodium (Na), potassium (K), rubidium (Rb), cesium (Cs), etc.); alkaline earth metal (e.g., beryllium (Be), magnesium (Mg), calcium (Ca), strontium (Sr), barium (Ba), etc.); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (e.g., zinc (Zn), indium (In), tin (Sn), etc.); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of the metalloid are silicon (Si), antimony (Sb), tellurium (Te), and the like.

Examples of the non-metal are oxygen (O), halogen (e.g., F, Cl, Br, I, etc.), and the like.

Examples of the compound including element EL1 and element EL2 are metal oxide, metal halide (e.g., metal fluoride, metal chloride, metal bromide, metal iodide, etc.), metalloid halide (e.g., metalloid fluoride, metalloid chloride, metalloid bromide, metalloid iodide, etc.), metal telluride, or any combination thereof.

Examples of the metal oxide are tungsten oxide (e.g., WO, W₂O₃, WO₂, WO₃, W₂O₅, etc.), vanadium oxide (e.g., VO, V₂O₃, VO₂, V₂O₅, etc.), molybdenum oxide (e.g., MoO, Mo₂O₃, MoO₂, MoOs, Mo₂O₅, etc.), rhenium oxide (e.g., ReO₃, etc.), and the like.

Examples of the metal halide are alkali metal halide, alkaline earth metal halide, transition metal halide, post-transition metal halide, lanthanide metal halide, and the like.

Examples of the alkali metal halide are LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of the alkaline earth metal halide are BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, Srl₂, Bal₂, and the like.

Examples of the transition metal halide are titanium halide (e.g., TiF₄, TiCl₄, TiBr₄, TiI₄, etc.), zirconium halide (e.g., ZrF₄, ZrCl₄, ZrBr₄, ZrI₄, etc.), hafnium halide (e.g., HfF₄, HfCl₄, HfBr₄, HfI₄, etc.), vanadium halide (e.g., VF₃, VCl₃, VBr₃, VI₃, etc.), niobium halide (e.g., NbF₃, NbCl₃, NbBr₃, NbI₃, etc.), tantalum halide (e.g., TaF₃, TaCl₃, TaBr₃, TaI₃, etc.), chromium halide (e.g., CrF₃, CrCl₃, CrBr₃, CrI₃, etc.), molybdenum halide (e.g., MoF₃, MoCl₃, MoBr₃, MoIs, etc.), tungsten halide (e.g., WF₃, WCls, WBr₃, WI₃, etc.), manganese halide (e.g., MnF₂, MnCl₂, MnBr₂, MnI₂, etc.), technetium halide (e.g., TcF₂, TcCl₂, TcBr₂, TcI₂, etc.), rhenium halide (e.g., ReF₂, ReCl₂, ReBr₂, ReI₂, etc.), iron halide (e.g., FeF₂, FeCl₂, FeBr₂, FeI₂, etc.), ruthenium halide (e.g., RuF₂, RuCl₂, RuBr₂, RuI₂, etc.), osmium halide (e.g., OsF₂, OsCl₂, OsBr₂, OsI₂, etc.), cobalt halide (e.g., CoF₂, CoCl₂, CoBr₂, CoI₂, etc.), rhodium halide (e.g., RhF₂, RhCl₂, RhBr₂, RhI₂, etc.), iridium halide (e.g., IrF₂, IrCl₂, IrBr₂, IrI₂, etc.), nickel halide (e.g., NiF₂, NiCl₂, NiBr₂, NiI₂, etc.), palladium halide (e.g., PdF₂, PdCl₂, PdBr₂, PdI₂, etc.), platinum halide (e.g., PtF₂, PtCl₂, PtBr₂, PtI₂, etc.), copper halide (e.g., CuF, CuCl, CuBr, CuI, etc.), silver halide (e.g., AgF, AgCl, AgBr, AgI, etc.), gold halide (e.g., AuF, AuCl, AuBr, AuI, etc.), and the like.

Examples of the post-transition metal halide are zinc halide (e.g., ZnF₂, ZnCl₂, ZnBr₂, ZnI₂, etc.), indium halide (e.g., InI₃, etc.), tin halide (e.g., SnI₂, etc.), and the like.

Examples of the lanthanide metal halide are YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and the like.

Examples of the metalloid halide are antimony halide (e.g., SbCl₅, etc.) and the like.

Examples of the metal telluride are alkali metal telluride (e.g., Li₂Te, Na₂Te, K₂Te, Rb₂Te, Cs₂Te, etc.), alkaline earth metal telluride (e.g., BeTe, MgTe, CaTe, SrTe, BaTe, etc.), transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal telluride (e.g., ZnTe, etc.), lanthanide metal telluride (e.g., LaTe, CeTe, PrTe, NdTe, PmTe, EuTe, GdTe, TbTe, DyTe, HoTe, ErTe, TmTe, YbTe, LuTe, etc.), and the like.

In an embodiment, when the hole transport layer 120 includes a layer including a p-dopant, the content of p-dopant in the layer including the p-dopant may be in a range of about 0.1 vol % to about 10 vol %, for example, about 0.5 vol % to about 5 vol %.

The thickness of the layer including the p-dopant may be in a range of about 30 Å to about 2,000 Å, for example, about 100 Å to about 1,500 Å.

### [Electron Transport Region]

Charge auxiliary layers arranged between the activation layer 140 and the second electrode 170 may be collectively referred to as an electron transport region.

The electron transport region may have i) a single-layer structure consisting of a single layer consisting of a single material, ii) a single-layer structure consisting of a single layer consisting of multiple materials that are different from each other, or iii) a multi-layer structure including multiple layers including multiple materials that are different from each other.

The electron transport region may include the buffer layer 150, a hole blocking layer (not shown), the electron transport layer 160, an electron injection layer (not shown), or any combination thereof.

For example, the electron transport region may have an electron transport layer/electron injection layer structure, a hole blocking layer/electron transport layer/electron injection layer structure, a buffer layer/electron transport layer/electron injection layer structure, or a buffer layer/electron transport layer structure, wherein constituent layers of each structure are sequentially stacked from the activation layer 140.

In an embodiment, the electron transport region (e.g., the buffer layer, the hole blocking layer, or the electron transport layer in the electron transport region) may include a metal-free compound including at least one π electron-deficient nitrogen-containing C₁-C₆₀ cyclic group.

For example, the electron transport region may include a compound represented by Formula 601:

[Ar₆₀₁]ₓₑ₁₁-[(L₆₀₁)ₓₑ₁-R₆₀₁]ₓₑ₂₁ Formula 601
wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁, Q₆₀₂, and Q₆₀₃ may each be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, when xe11 in Formula 601 is 2 or more, two or more of Ar₆₀₁ may be linked to each other via a single bond.

In one or more embodiments, Ar₆₀₁ in Formula 601 may be a substituted or unsubstituted anthracene group.

In one or more embodiments, the electron transport region may include a compound represented by Formula 601-1:

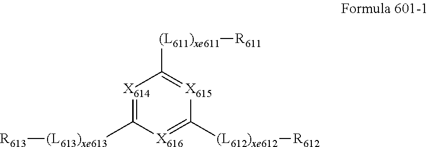

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁, L₆₁₂, and L₆₁₃ may each be the same as described in connection with L₆₀₁,
xe611, xe612, and xe613 may each be the same as described in connection with xe1,
R₆₁₁, R₆₁₂, and R₆₁₃ may each be the same as described in connection with R₆₀₁, and
R₆₁₄, R₆₁₅, and R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611, xe612, and xe613 in Formulae 601 and 601-1 may each independently be 0, 1, or 2.

The electron transport region may include: one of Compounds ET1 to ET45; 2,9-dimethyl-4,7-diphenyl-1,10-phenanthroline (BCP); 4,7-diphenyl-1,10-phenanthroline (Bphen); Alq₃; BAIq; TAZ; NTAZ; or any combination thereof:

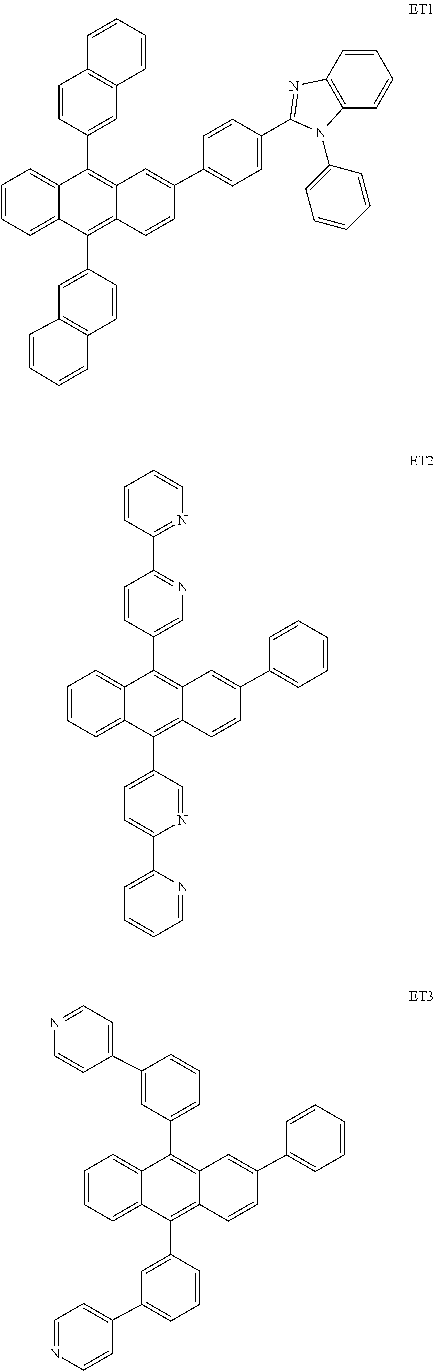 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

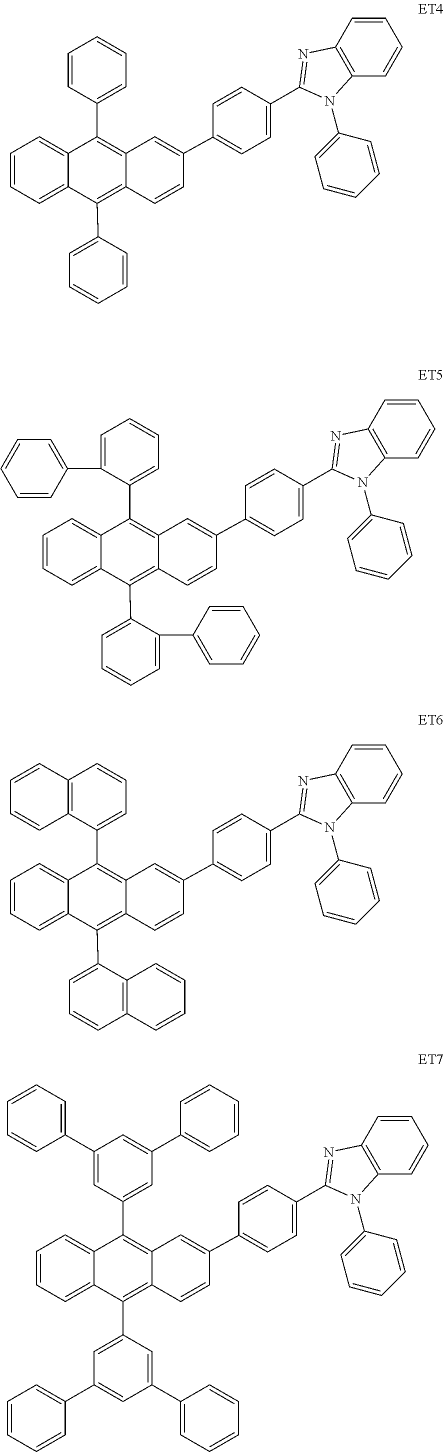 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

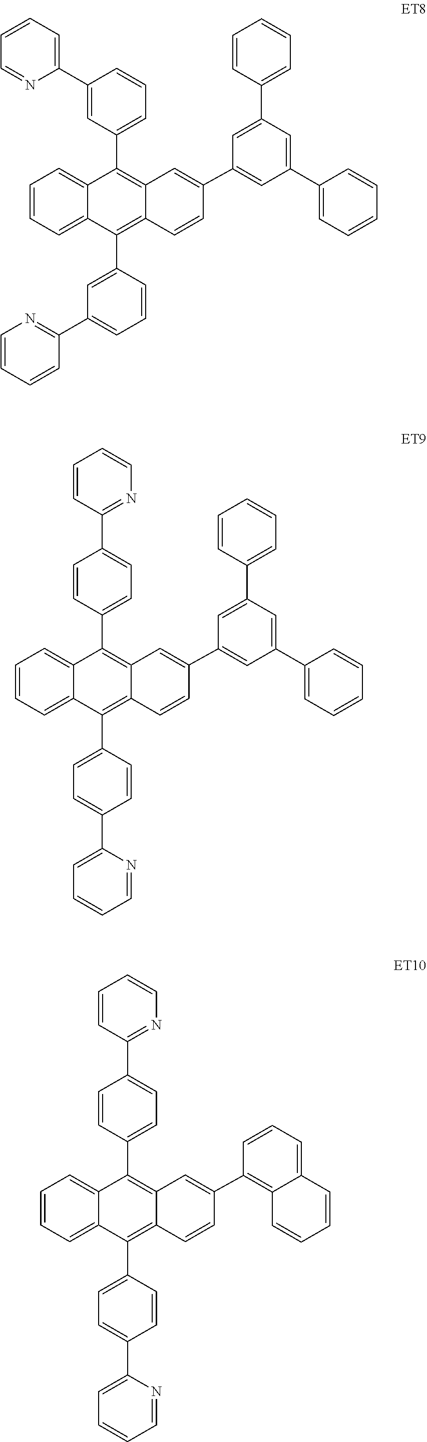 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

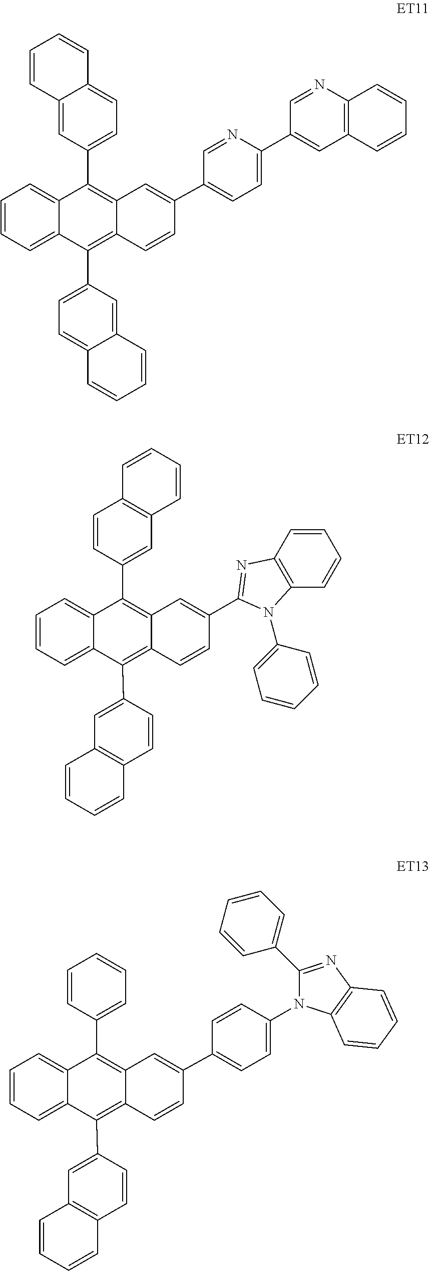 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

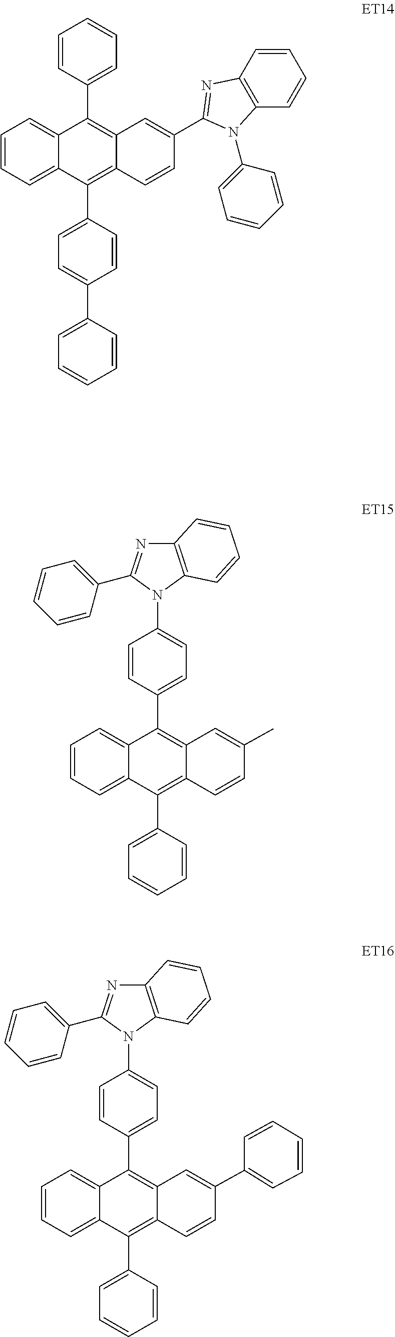 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

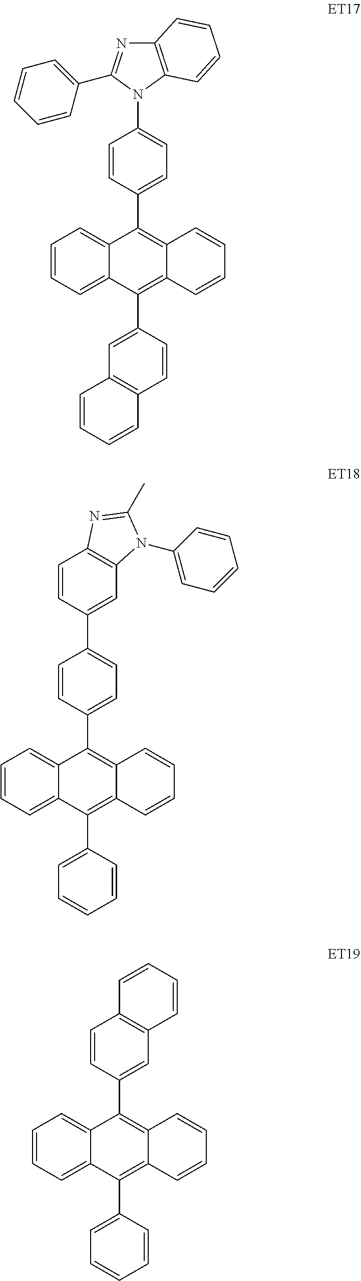

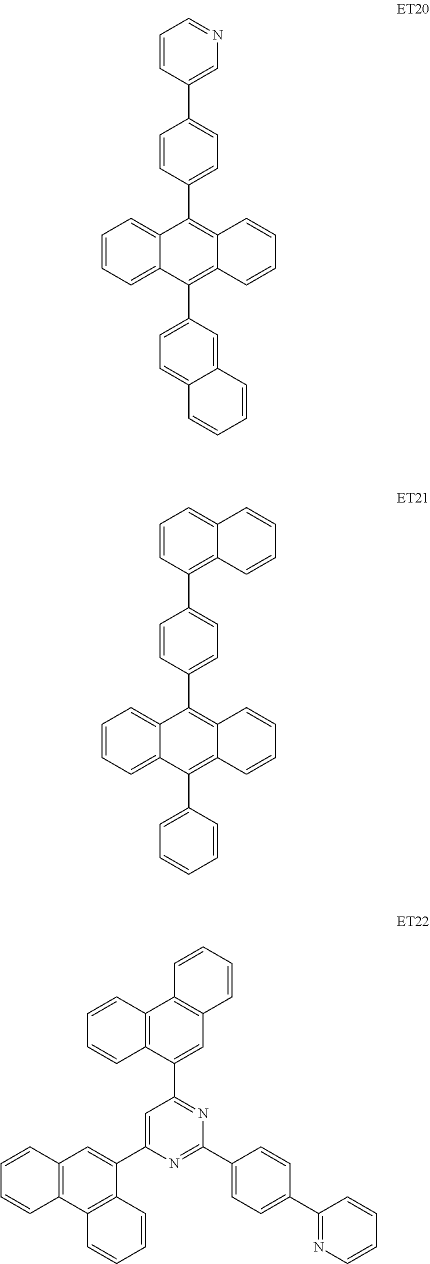

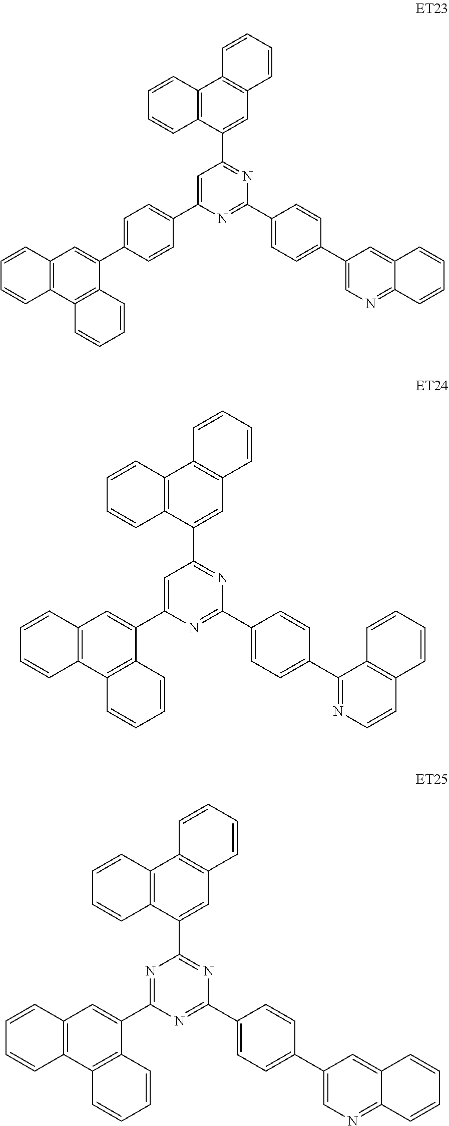 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

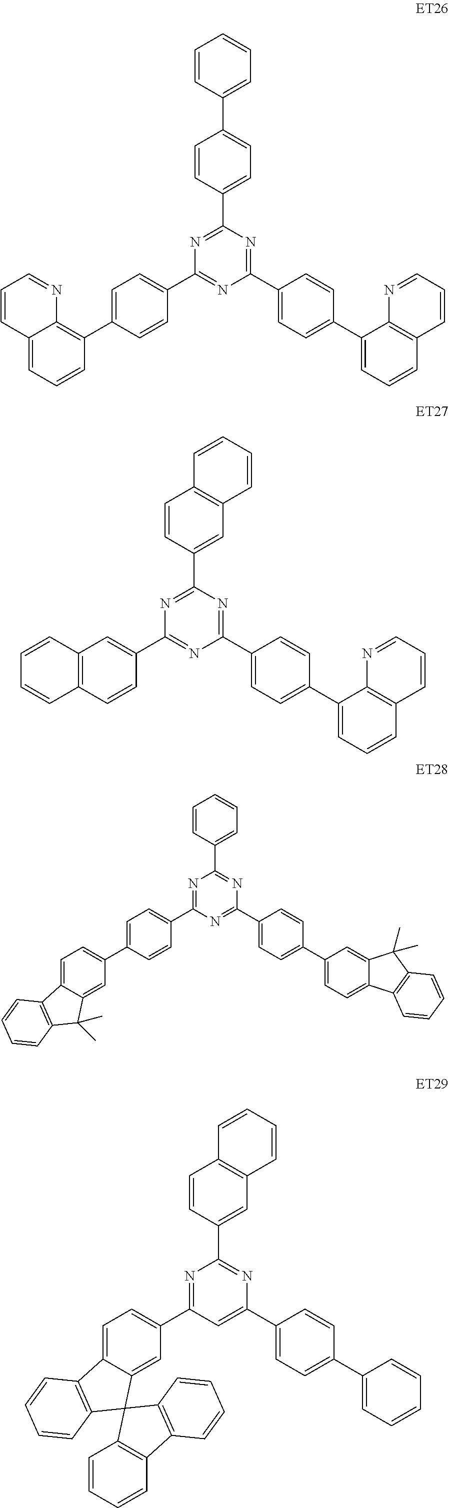 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

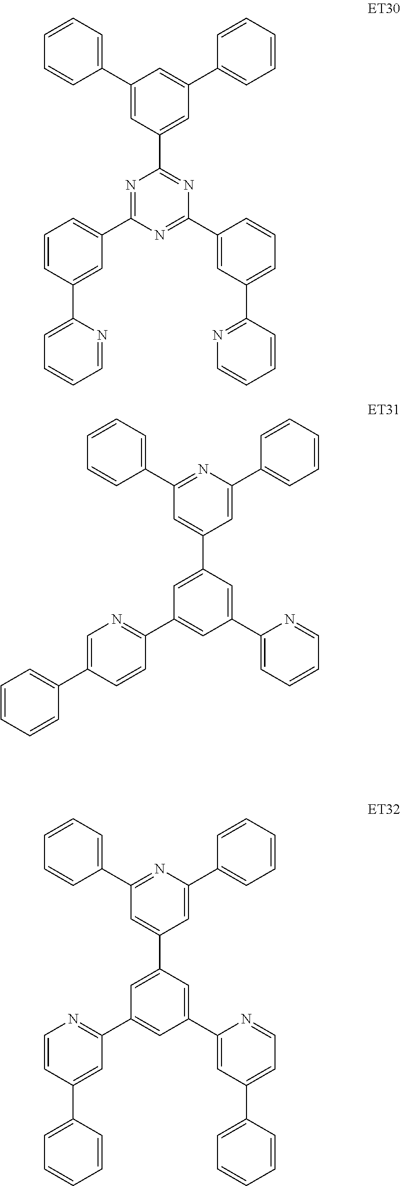 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

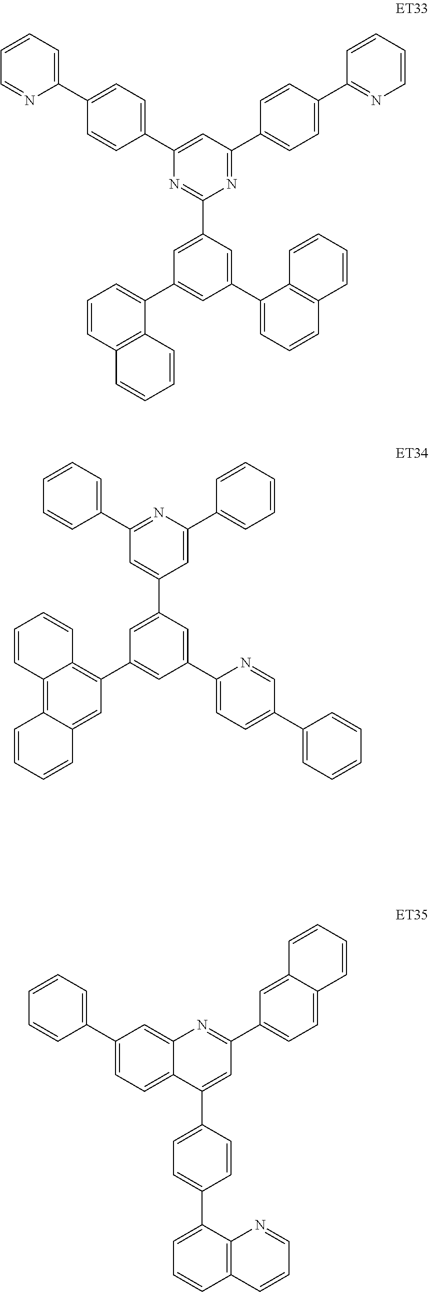 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

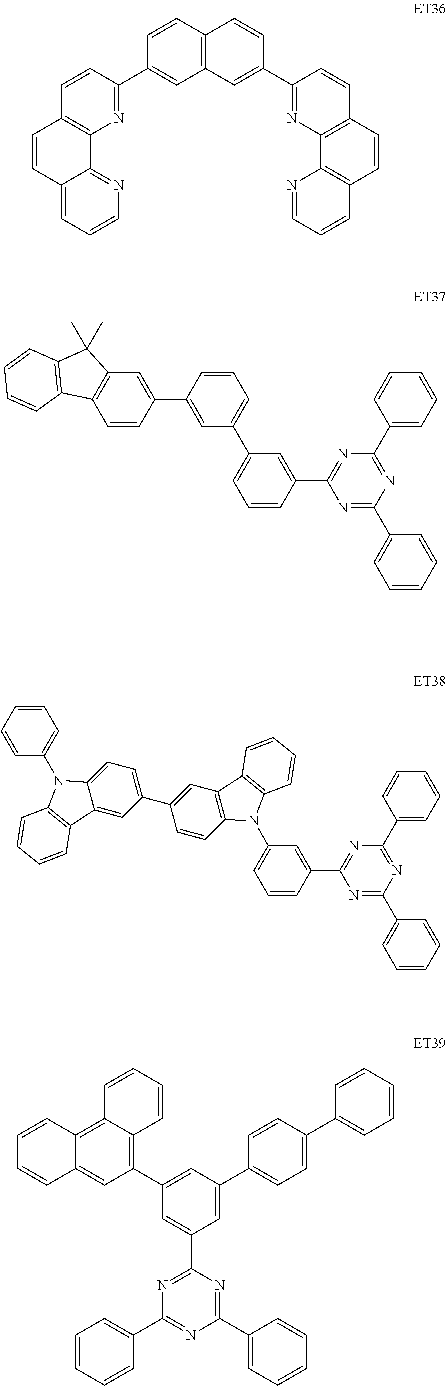 [SMILES: c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1]

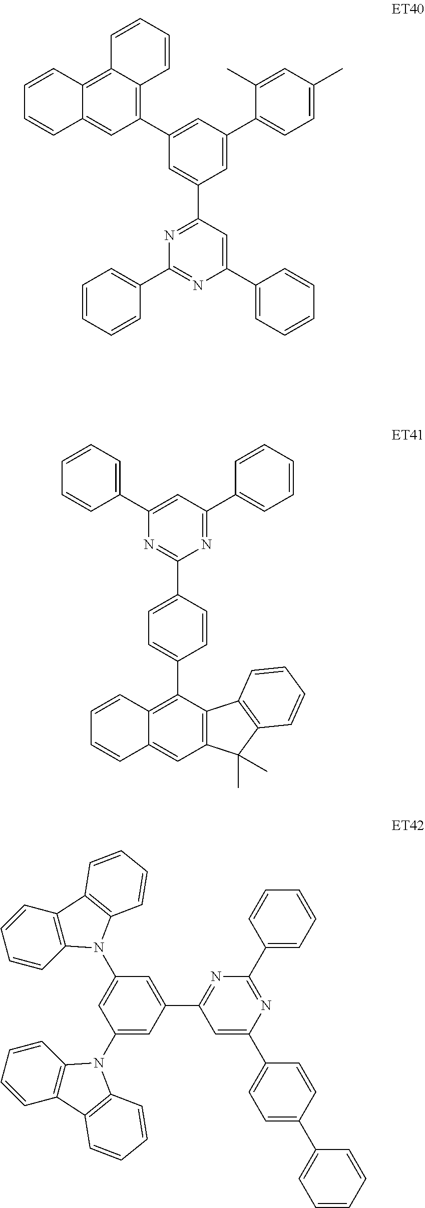 [SMILES: Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

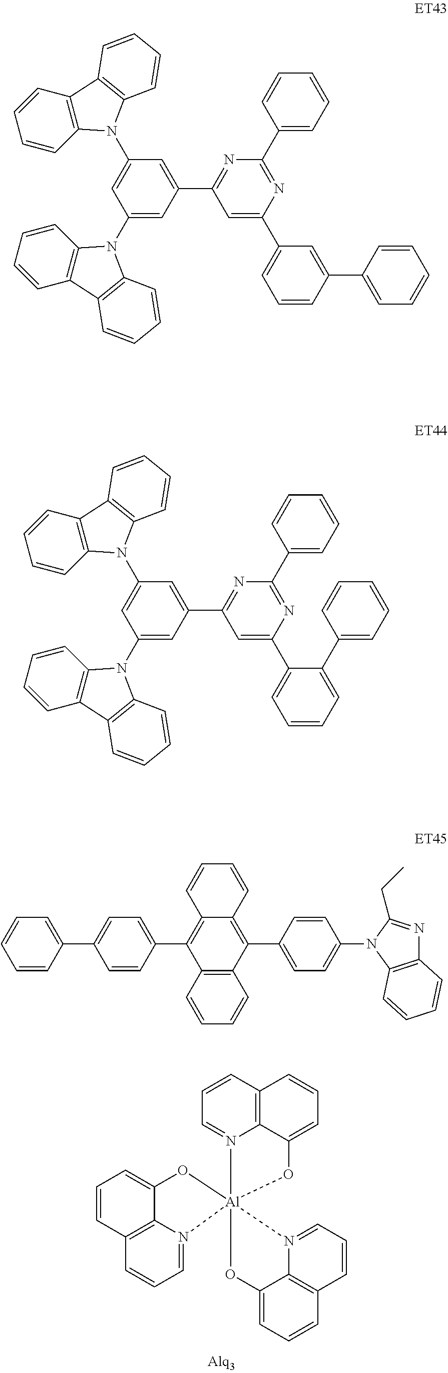

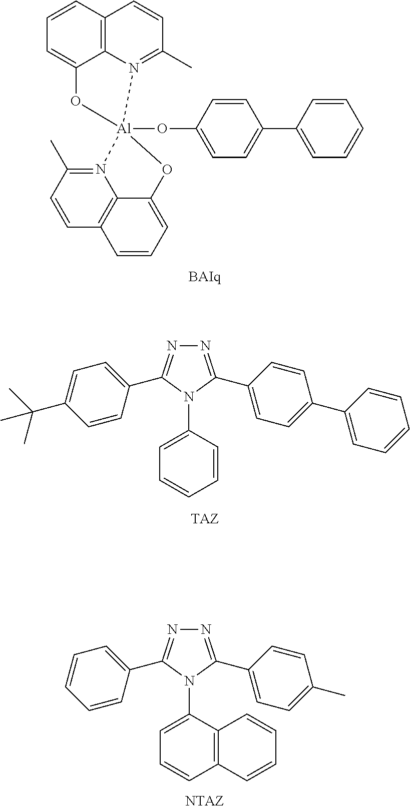

The thickness of the electron transport region may be in a range of about 50 Å to about 5,000 Å, for example, about 100 Å to about 4,000 Å. When the electron transport region includes a buffer layer, a hole blocking layer, an electron transport layer, or any combination thereof, the thicknesses of the buffer layer and the hole blocking layer may each independently be in a range of about 20 Å to about 1,000 Å, for example, about 30 Å to about 300 Å, and the thickness of the electron transport layer may be in a range of about 100 Å to about 3,000 Å, for example, about 150 Å to about 2,000 Å. When the thicknesses of the buffer layer, the hole blocking layer, and/or the electron transport layer are within the above-described ranges, satisfactory electron transporting characteristics may be obtained without a substantial increase in driving voltage.

The electron transport region (e.g., the electron transport layer in the electron transport region) may further include, in addition to the above-described materials, a metal-containing material.

The metal-containing material may include an alkali metal complex, an alkaline earth metal complex, or any combination thereof. The metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. A ligand coordinated with the metal ion of the alkali metal complex or the alkaline earth-metal complex may include hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, a phenanthroline, cyclopentadiene, or any combination thereof.

For example, the metal-containing material may include a Li complex. The Li complex may include, for example, Compound ET-D1 (LiQ) or ET-D2:

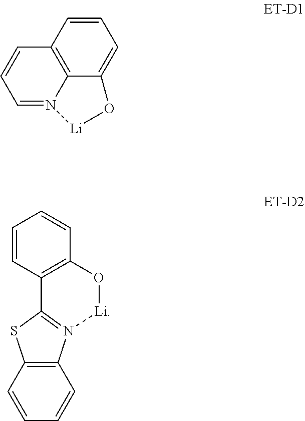

The electron transport region may include an electron injection layer that facilitates injection of electrons. The electron injection layer may be in direct contact with the second electrode 170.

The electron injection layer may have i) a single-layer structure consisting of a single layer consisting of a single material, ii) a single-layer structure consisting of a single layer consisting of multiple layers that are different from each other, or iii) a multi-layer structure including multiple layers including multiple materials that are different from each other.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (e.g., fluorides, chlorides, bromides, iodides, etc.), or tellurides of the alkali metal, the alkaline earth metal, and the rare earth metal, or any combination thereof.

The alkali metal-containing compound may include: alkali metal oxide, such as Li₂O, Cs₂O, K₂O, and the like; alkali metal halide, such as LiF, NaF, CsF, KF, LiI, NaI, CsI, KI, and the like; or any combination thereof. The alkaline earth metal-containing compound may include an alkaline earth metal compound, such as BaO, SrO, CaO, BaₓSr₁₋ₓO (wherein x is a real number satisfying 0<x<1), BaₓCa₁₋ₓO (wherein x is a real number satisfying 0<x<1), and the like. The rare earth metal-containing compound may include YbF₃, ScF₃, SC₂O₃, Y₂O₃, Ce₂O₃, GdF₃, TbF₃, YbI₃, Scl₃, TbI₃, or any combination thereof. In an embodiment, the rare earth metal-containing compound may include lanthanide metal telluride. Examples of the lanthanide metal telluride are LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, HO₂Te₃, Er₂Te₃, Tm₂Te₃, Yb₂Te₃, Lu₂Te₃, and the like.

The alkali metal complex, the alkaline earth-metal complex, and the rare earth metal complex may include i) one of ions of the alkali metal, the alkaline earth metal, and the rare earth metal and ii) a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (e.g., a compound represented by Formula 601).

In an embodiment, the electron injection layer may consist of i) an alkali metal-containing compound (e.g., alkali metal halide), ii) a) an alkali metal-containing compound (e.g., alkali metal halide); and b) an alkali metal, an alkaline earth metal, a rare earth metal, or any combination thereof. For example, the electron injection layer may be a KI:Yb co-deposited layer, an RbI:Yb co-deposited layer, or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

The thickness of the electron injection layer may be in a range of about 1 Å to about 100 Å, for example, about 3 Å to about 90 Å. When the thickness of the electron injection layer is within the above-described range, satisfactory electron injection characteristics may be obtained without a substantial increase in driving voltage.

### [Second Electrode 170]

The second electrode 170 is arranged on the above-described electron transport region. The second electrode 170 may be a cathode, and as a material for forming the second electrode 170, a metal, an alloy, an electrically conductive compound, or any combination thereof, each having a low work function, may be used.

The second electrode 170 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 170 may be a transmissive electrode, a semi-transmissive electrode, or a reflective electrode.

The second electrode 170 may have a single-layer structure or a multi-layer structure including multiple layers.

### [Capping Layer]

A first capping layer may be arranged outside the first electrode 110, and/or a second capping layer may be arranged outside the second electrode 170.

The first capping layer and/or the second capping layer may prevent impurities, such as water, oxygen, and the like, from entering the organic photodetector 10, thereby increasing the reliability of the organic photodetector 10.

Each of the first capping layer and the second capping layer may include a material having a refractive index of 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In an embodiment, at least one of the first capping layer and the second capping layer may each independently include an amine group-containing compound.

In one or more embodiments, at least one of the first capping layer and the second capping layer may each independently include a compound represented by Formula 201, a compound represented by Formula 202, or any combination thereof.

In one or more embodiments, at least one of the first capping layer and the second capping layer may each independently include one of Compounds HT28 to HT33, one of Compounds CP1 to CP6, β-NPB, or any combination thereof:

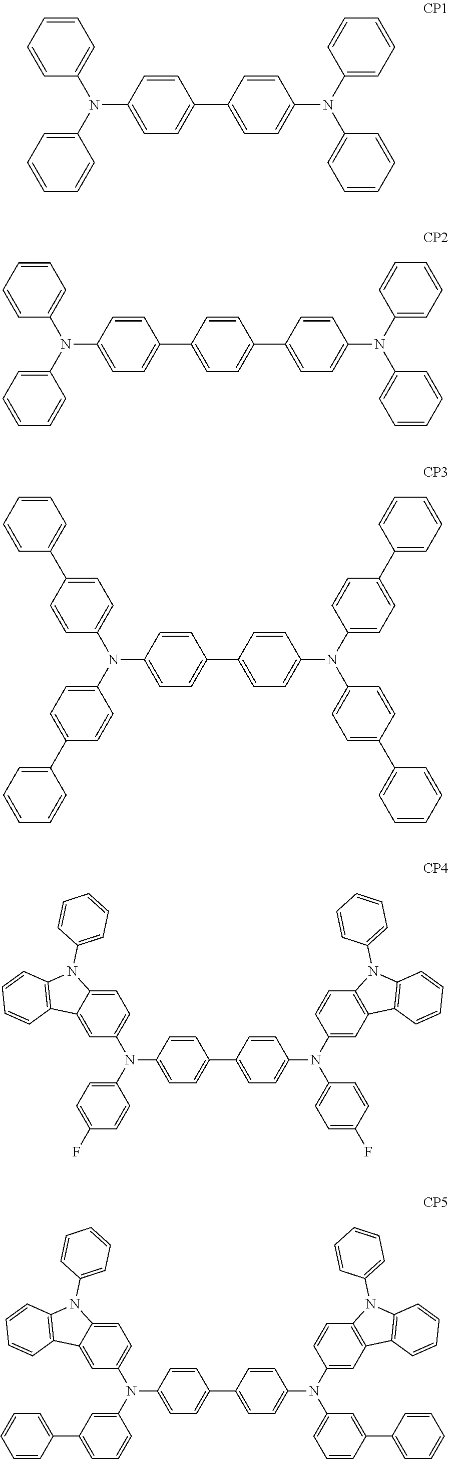 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

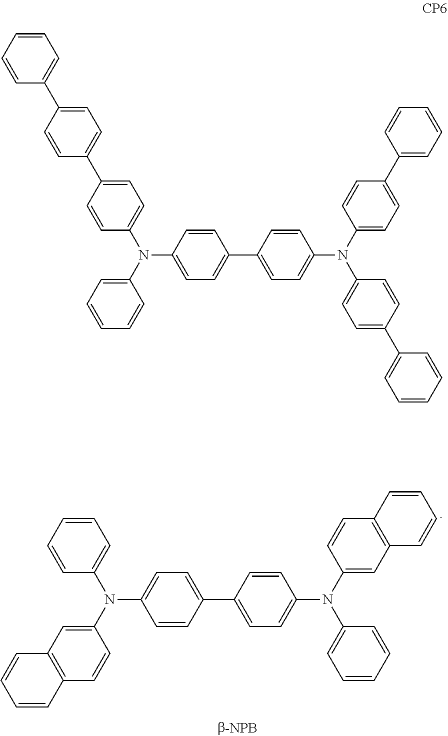 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Electronic Apparatus]

An electronic apparatus including the above-described organic photodetector may be provided. For example, the electronic apparatus may further include a light-emitting device.

Accordingly, the electronic apparatus according to an embodiment may include: a substrate including a photodetection region and an emission region;
an organic photodetector arranged on the photodetection region; and
a light-emitting device arranged on the emission region,
wherein the organic photodetector may include: a first pixel electrode; a counter electrode facing the first pixel electrode; and a hole transport region, an activation layer, and an electron transport region, which are sequentially arranged between the first pixel electrode and the counter electrode,
the light-emitting device may include: a second pixel electrode; the counter electrode facing the second pixel electrode; and the hole transport region, an emission layer, and the electron transport region, which are sequentially arranged between the second pixel electrode and the counter electrode,
the first pixel electrode and the activation layer may be arranged in correspondence with the photodetection region,
the second pixel electrode and the emission layer may be arranged in correspondence with the emission region,
the hole transport region, the electron transport region, and the counter electrode may be arranged throughout the photodetection region and the emission region, and
the electron transport region and the activation layer of the organic photodetector may be in contact with each other, and a mean square roughness (R_{q}) value of a surface of the activation layer in a direction of contact with the electron transport region may be 9 nm or more.

The hole transport region and the electron transport region may each be the same as described above.

For example, a hole transport layer, which includes a layer including a p-dopant, a hole transport layer, an auxiliary layer, a buffer layer, an electron transport layer, and a counter electrode may be arranged throughout the photodetection region and the emission region.

The electronic apparatus may be applied to various displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (e.g., meters for a vehicle, an aircraft, and a vessel), projectors, and the like.

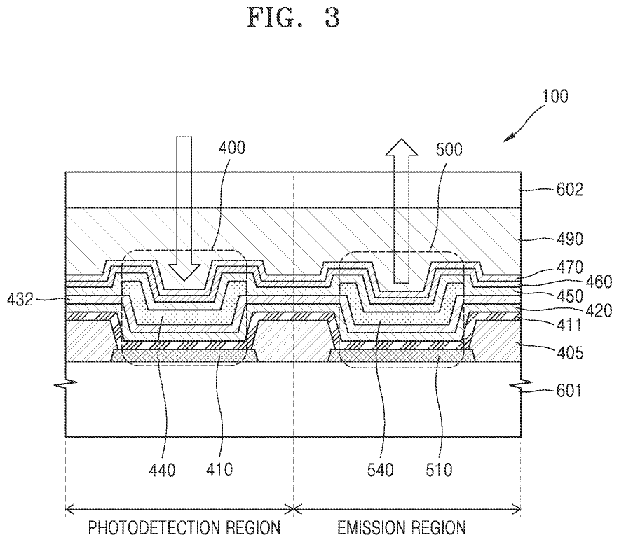

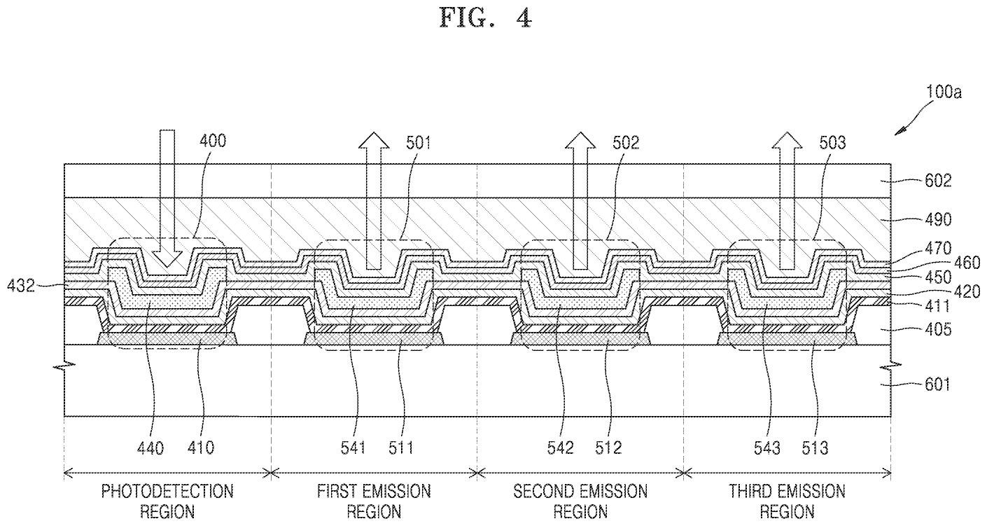

### [Descriptions of FIGS. 3 and 4]

FIG. 3 is a schematic cross-sectional view of an electronic apparatus 100 according to an embodiment.

Referring to FIG. 3, the electronic apparatus 100 includes an organic photodetector 400 and a light-emitting device 500 between a substrate 601 and a substrate 602.

The substrate 601 and the substrate 602 may each be a flexible substrate, a glass substrate, or a metal substrate. A buffer layer (not shown) and a thin-film transistor (not shown) may be arranged on the substrate 601.

The buffer layer may prevent infiltration of impurities through the substrate 601, and may provide a smooth surface on the substrate 601. The thin-film transistor may be arranged on the buffer layer, and may include an activation layer, a gate electrode, a source electrode, and a drain electrode.

The thin-film transistor may be electrically connected to the light-emitting device 500 to drive the light-emitting device 500. One of the source electrode and drain electrode may be electrically connected to a second pixel electrode 510 of the light-emitting device 500.

Another thin-film transistor may be electrically connected to the organic photodetector 400. One of the source electrode and drain electrode may be electrically connected to a first pixel electrode 410 of the organic photodetector 400.

The organic photodetector 400 may include the first pixel electrode 410, a hole injection layer 411, a hole transport layer 420, an optical auxiliary layer 432, an activation layer 440, a buffer layer 450, an electron transport layer 460, and a counter electrode 470.

In one or more examples, the first pixel electrode 410 may be an anode, and the counter electrode 470 may be a cathode. That is, by applying a reverse bias between the first pixel electrode 410 and the counter electrode 470 to drive the organic photodetector 400, the electronic apparatus 100 may detect light incident on the organic photodetector 400, generate charges, and extract the charges as a current.

The light-emitting device 500 may include the second pixel electrode 510, the hole injection layer 411, the hole transport layer 420, the optical auxiliary layer 432, an emission layer 540, the buffer layer 450, the electron transport layer 460, and the counter electrode 470.

In an embodiment, mean square roughness (R_{q}) value of top and bottom surfaces of the counter electrode on the second pixel electrode may each be less than 5 nm. That is, the top and bottom surfaces of the counter electrode in the light-emitting device are smooth. This is different from the top and bottom surfaces of the counter electrode in the organic photodetector, which are uneven. “Top surface” and “bottom surface,” as used herein, refer to the surfaces with respect to the orientation of FIG. 3 and FIG. 4.

In an embodiment, the electron transport region and the emission layer of the light-emitting device may be in contact with each other, and a mean square roughness (R_{q}) value of a top surface of the emission layer may be less than 5 nm. For example, a surface of the emission layer 540 of the light-emitting device in contact with the buffer layer 450 may have a mean square roughness (R_{q}) value of less than 5 nm, and may be characterized as smooth.

This is in contrast to the fact that, in the organic photodetector, an interface between the electron transport region (e.g., the buffer layer 450) and the activation layer may have a mean square roughness (R_{q}) value of 9 nm, and may be characterized as an uneven surface.

In an embodiment, the electron transport region arranged throughout the photodetection region and the emission region may include an electron transport layer, mean square roughness (R_{q}) values of top and bottom surfaces of the electron transport layer of the light-emitting device may each be less than 5 nm, and mean square roughness (R_{q}) values of top and bottom surfaces of the electron transport layer of the organic photodetector may each be 9 nm or more.

For example, the thickness of the electron transport layer of the light-emitting device may be in a range of about 100 Å to about 3,000 Å. For example, the thickness of the electron transport layer of the light-emitting device may be in a range of about 150 Å to about 2,000 Å.

When the thickness of the electron transport layer is 150 Å or more, tunneling of electrons may be difficult.

The electron transport layer may be arranged throughout the photodetection region and the emission region, and may have a thickness in a range of about 150 Å to about 2,000 Å. Since the electron transport layer of the organic photodetector is uneven, the smallest thickness of the electron transport layer may be less than 150 Å, and thus, tunneling of electrons may occur, and the efficiency of the organic photodetector may be improved. This may equally apply to all other layers included in the electron transport region of the organic photodetector.

In an embodiment, the second pixel electrode 510 may be an anode, and the counter electrode 470 may be a cathode. That is, in the light-emitting device 500, holes injected from the second pixel electrode 510 and electrons injected from the counter electrode 470 may recombine in the emission layer 540 to generate excitons, and the excitons may transition from an excited state to a ground state, thereby generating light.

The first pixel electrode 410 and the second pixel electrode 510 are similar to the first electrode 110, and redundant description will not be provided.

A pixel defining film 405 is formed at edges of the first pixel electrode 410 and the second pixel electrode 510. The pixel defining film 405 may define a pixel region, and may electrically insulate between the first pixel electrode 410 and the second pixel electrode 510. The pixel defining film 405 may include, for example, various known organic insulating materials (e.g., silicon-based materials, etc.), inorganic insulating materials, or organic/inorganic composite insulating materials. The pixel defining film 405 may be a transmissive film that transmits visible light, or a blocking film that blocks visible light.

The hole injection layer 411, the hole transport layer 420, and the optical auxiliary layer 432, which are common layers, are formed sequentially on the first pixel electrode 410 and the second pixel electrode 510. For descriptions of the hole injection layer 411, the hole transport layer 420, and the optical auxiliary layer 432, related descriptions provided herein may be referred to.

The activation layer 440 is formed on the optical auxiliary layer 432 to correspond to the photodetection region. As the activation layer 440 is similar to the activation layer 140, redundant descriptions will not be provided.

The emission layer 540 is formed on the optical auxiliary layer 432 to correspond to the emission region. In an embodiment, the light-emitting device 500 may further include, between the second pixel electrode 510 and the emission layer 540, an electron blocking layer (not shown) arranged in correspondence with the emission region.

As common layers for the entirety of the photodetection region and the emission region, the buffer layer 450, the electron transport layer 460, and the counter electrode 470 are sequentially formed on the activation layer 440 and the emission layer 540. For descriptions of the buffer layer 450, the electron transport layer 460, and the counter electrode 470, the descriptions of the buffer layer, the electron transport layer, and the second electrode 170 provided herein may be referred to.

Each of the hole injection layer 411, the hole transport layer 420, the optical auxiliary layer 432, the buffer layer 450, and/or the electron transport layer 460 may be arranged throughout the photodetection region and the emission region.

As such, the manufacturing process of the electronic apparatus 100 may be simplified by arranging common layers for the organic photodetector 400 and the light-emitting device 500, existing functional layer materials used for the light-emitting device 500 may also be used for the organic photodetector 400, and thus, the organic photodetector 400 may be arranged in-pixel in the electronic apparatus.

In an embodiment, an electron injection layer (not shown) may be further included between the electron transport layer 460 and the counter electrode 470.

A capping layer (not shown) may be arranged on the counter electrode 470. A material for forming the capping layer may include the organic material and/or the inorganic material described above. The capping layer may facilitate efficient emission of light generated from the light-emitting device 500, in addition to having a protective function for the organic photodetector 400 and the light-emitting device 500.

An encapsulation portion 490 may be arranged on the capping layer. The encapsulation portion 490 may be arranged on the organic photodetector 400 and the light-emitting device 500 to protect the organic photodetector 400 and the light-emitting device 500 from water or oxygen. The encapsulation portion 490 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, etc.), an epoxy-based resin (e.g., aliphatic glycidyl ether (AGE), etc.), or any combination thereof; or a combination of the inorganic film and the organic film.

The electronic apparatus 100 may be, for example, a display apparatus. Since the electronic apparatus 100 includes both the organic photodetector 400 and the light-emitting device 500, the electronic apparatus 100 may be a display apparatus having a light detection function.

In FIG. 3, the electronic apparatus 100 includes one light-emitting device 500, but as shown in FIG. 4, an electronic apparatus 100a according to an embodiment may include the organic photodetector 400, a first light-emitting device 501, a second light-emitting device 502, and a third light-emitting device 503.

Components of FIG. 4 are similar to those of FIG. 3 and the electronic apparatus 100, and any redundant descriptions will be omitted.

The first light-emitting device 501 may include a second pixel electrode 511, the hole injection layer 411, the hole transport layer 420, the optical auxiliary layer 432, a first emission layer 541, the buffer layer 450, the electron transport layer 460, and the counter electrode 470.

The second light-emitting device 502 may include a third pixel electrode 512, the hole injection layer 411, the hole transport layer 420, the optical auxiliary layer 432, a second emission layer 542, the buffer layer 450, the electron transport layer 460, and the counter electrode 470.

The third light-emitting device 503 may include a fourth pixel electrode 513, the hole injection layer 411, the hole transport layer 420, the optical auxiliary layer 432, a third emission layer 543, the buffer layer 450, the electron transport layer 460, and the counter electrode 470.

The second pixel electrode 511, the third pixel electrode 512, and the fourth pixel electrode 513 may respectively be arranged to correspond to a first emission region, a second emission region, and a third emission region, and may be understood by referring to the descriptions of the first electrode 110 provided herein.

The first emission layer 541 may be arranged in correspondence with the first emission region and emit first color light, the second emission layer 542 may be arranged in correspondence with the second emission region and emit second color light, and the third emission layer 543 may be arranged in correspondence with the third emission region and emit third color light.

The maximum emission wavelength of the first color light, the maximum emission wavelength of the second color light, and the maximum emission wavelength of the third color light may be identical to or different from each other. For example, the maximum emission wavelength of the first color light and the maximum emission wavelength of the second color light may each be longer than the maximum emission wavelength of the third color light.

For example, the first color light may be red light, the second color light may be green light, and the third color light may be blue light, but embodiments are not limited thereto. Accordingly, the electronic apparatus 100a may emit full color light. The first color light, the second color light, and the third color light are not limited to red light, green light, and blue light, respectively, and may be any combination of light of different colors, as long as mixed light thereof is white light.

The organic photodetector 400, the first light-emitting device 501, the second light-emitting device 502, and the third light-emitting device 503 may each be a subpixel of a pixel. In an embodiment, the pixel may include at least one organic photodetector 400.

The electronic apparatus 100a may be a display apparatus. Since the electronic apparatus 100a includes all of the organic photodetector 400, the first light-emitting device 501, the second light-emitting device 502, and the third light-emitting device 503, the electronic apparatus 100a may be a full-color display apparatus having a light detection function.

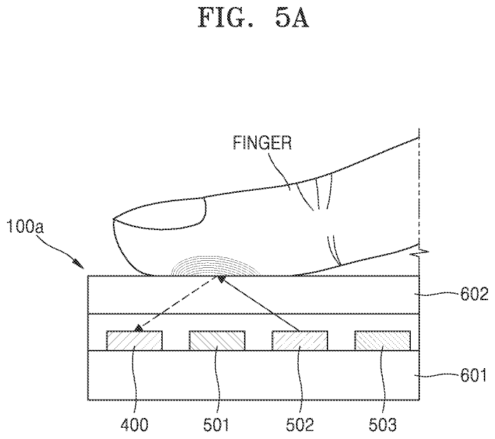

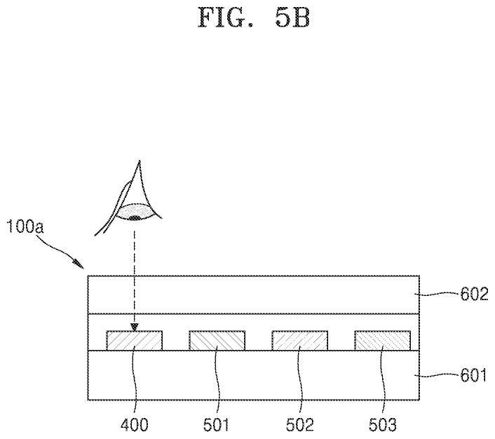

### [Descriptions of FIGS. 5A and 5B]

In the electronic apparatus 100a shown in FIG. 5A, the organic photodetector 400 and the first to third light-emitting devices 501, 502, and 503 are arranged between the substrate 601 and the substrate 602.

For example, red light, green light, and blue light may be respectively emitted from the first light-emitting device 501, the second light-emitting device 502, and the third light-emitting device 503.

The electronic apparatus 100a according to an embodiment may have a function of detecting an object in contact with or in close proximity to the electronic apparatus 100a, for example, the fingerprint of a finger. For example, as shown in FIG. 5A, at least some light emitted from the second light-emitting device 502 and reflected by the fingerprint of a user may be re-incident on the organic photodetector 400, and thus, the organic photodetector 400 may detect the reflected light. Since ridges in the fingerprint pattern of a finger are in close contact with the substrate 602, the organic photodetector 400 may selectively acquire the fingerprint pattern of a user, for example, image information of the ridges. FIG. 5A shows an example in which information of an object in contact with the electronic apparatus 100a is obtained by using light emitted from the second light-emitting device 502. However, the information may be obtained in the same manner by using light emitted from the first light-emitting device 501 and/or the third light-emitting device 503.

Meanwhile, as shown in FIG. 5B, the electronic apparatus 100a according to an embodiment may detect an object that is not in contact with the electronic apparatus 100a.

### [Manufacturing Method]

The layers constituting the hole transport region, the activation layer, and the layers constituting the electron transport region may be formed in certain regions by using one or more suitable methods selected from vacuum deposition, spin coating, casting, Langmuir-Blodgett (LB) deposition, ink-jet printing, laser-printing, and laser-induced thermal imaging (LITI).

When the layers constituting the hole transport region, the activation layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition rate in a range of about 0.01 Å/sec to about 100 Å/sec, depending on the material that is included in a layer to be formed and the structure of a layer to be formed.

Meanwhile, the deposition rate in depositing the activation layer (e.g., a layer including an n-type semiconductor compound) of the electronic apparatus according to an embodiment may be relatively lower than the deposition rate of other layers. For example, the deposition rate of the activation layer (e.g., a layer including an n-type semiconductor compound) of the electronic apparatus according to an embodiment may be in a range of about 0.1 Å/s to about 1.0 Å/s. For example, the deposition rate of the activation layer (e.g., a layer including an n-type semiconductor compound) of the electronic apparatus according to an embodiment may be in a range of about 0.2 Å/s to about 0.7 Å/s.

When the deposition rate is within the above range, a surface of the activation layer formed of the n-type semiconductor compound represented by Formula 2 or 3 may have a mean square roughness (R_{q}) value within the above range (9 nm or more).

When the deposition rate of the activation layer (e.g., a layer including an n-type semiconductor compound) is relatively high, for example, in a range of about 1.5 Å/s to about 6 Å/s, the surface of the activation layer formed of the n-type semiconductor compound represented by Formula 2 or 3 may have a mean square roughness (R_{q}) value outside the above range (less than 5 nm), and may become smooth.

### Definition of Terms

The term “C₃-C₆₀ carbocyclic group” as used herein refers to a cyclic group consisting of carbon only as a ring-forming atom and having 3 to 60 carbon atoms, and the term “C₁-C₆₀ heterocyclic group” as used herein refers to a cyclic group that has 1 to 60 carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the number of ring-forming atoms of the C₁-C₆₀ heterocyclic group may be from 3 to 61.

The term “cyclic group” as used herein may include both the C₃-C₆₀ carbocyclic group and the C₁-C₆₀ heterocyclic group.

The term “π electron-rich C₃-C₆₀ cyclic group” as used herein refers to a cyclic group that has 3 to 60 carbon atoms and does not include *—N═*′ as a ring-forming moiety, and the term “π electron-deficient nitrogen-containing C₁-C₆₀ cyclic group” as used herein refers to a heterocyclic group that has 1 to 60 carbon atoms and includes *—N═*′ as a ring-forming moiety.

For example,
the C₃-C₆₀ carbocyclic group may be i) Group T1 or ii) a condensed cyclic group in which two or more of Group T1 are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T3 and at least one Group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),
the π electron-deficient nitrogen-containing C₁-C₆₀ cyclic group may be i) Group T4, ii) a condensed cyclic group in which two or more of Group T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and
Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group” as used herein refer to a group condensed to any cyclic group, a monovalent group, or a polyvalent group (e.g., a divalent group, a trivalent group, a tetravalent group, etc.) according to the structure of a formula for which the corresponding term is used. For example, the “benzene group” may be a benzo group, a phenyl group, a phenylene group, or the like, which may be easily understood by one of ordinary skill in the art according to the structure of a formula including the “benzene group.”

Examples of the monovalent C₅-C₆₀ carbocyclic group and the monovalent C₁-C₆₀ heterocyclic group may include a C₅-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent hetero-condensed polycyclic group. Examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic hetero-condensed polycyclic group.

The term “C₁-C₆₀ alkyl group” as used herein refers to a linear or branched aliphatic hydrocarbon monovalent group having 1 to 60 carbon atoms, and examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof are an ethenyl group, a propenyl group, a butenyl group, and the like. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof are an ethynyl group, a propynyl group, and the like. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof are a methoxy group, an ethoxy group, an isopropyloxy group, and the like.

The term “C₃-C₁₀ cycloalkyl group” as used herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cyclooctyl group, an adamantyl group, a norbornyl (bicyclo[2.2.1]heptyl) group, a bicyclo[1.1.1]pentyl group, a bicyclo[2.1.1]hexyl group, a bicyclo[2.2.2]octyl group, and the like. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom, as ring-forming atoms, and examples thereof are a 1,2,3,4-oxatriazolidinyl group, a tetrahydrofuranyl group, a tetrahydrothiophenyl group, and the like. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent cyclic group that has 3 to 10 carbon atoms and at least one carbon-carbon double bond in the ring thereof and no aromaticity, and examples thereof are a cyclopentenyl group, a cyclohexenyl group, a cycloheptenyl group, and the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one double bond in the ring thereof. Examples of the C₁-C₁₀ heterocycloalkenyl group are a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group having two or more rings condensed with each other, only carbon atoms (e.g., having 8 to 60 carbon atoms) as ring-forming atoms, and non-aromaticity in its entire molecular structure. Examples of the monovalent non-aromatic condensed polycyclic group are an indenyl group, a fluorenyl group, a spiro-bifluorenyl group, a benzofluorenyl group, an indenophenanthrenyl group, an indenoanthracenyl group, and the like. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed with each other, at least one heteroatom, in addition to carbon atoms (e.g., having 1 to 60 carbon atoms), as a ring-forming atom, and non-aromaticity in its entire molecular structure. Examples of the monovalent non-aromatic condensed heteropolycyclic group are a 9,9-dihydroacridinyl group, a 9H-xanthenyl group, and the like. The term “divalent non-aromatic condensed heteropolycyclic group” as used herein refers to a divalent group having the same structure as the monovalent non-aromatic condensed heteropolycyclic group.

The term “C₆-C₆₀ aryloxy group” as used herein refers to —OA₁₀₂ (wherein A₁₀₂ is the C₆-C₆₀ aryl group), and the term “C₆-C₆₀ arylthio group” as used herein refers to —SA₁₀₃ (wherein A₁₀₃ is the C₆-C₆₀ aryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁, Q₂, and Q₃, Q₁₁, Q₁₂, and Q₁₃, Q₂₁, Q₂₂, and Q₂₃, and Q₃₁, Q₃₂, and Q₃₃ used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein refers to any atom other than a carbon atom. Examples of the heteroatom are O, S, N, P, Si, B, Ge, Se, and any combination thereof.

The term “third-row transition metal” as used herein includes Hf, Ta, W, Re, Os, Ir, Pt, Au, and the like.

The term “Ph” as used herein refers to a phenyl group, the term “Me” as used herein refers to a methyl group, the term “Et” as used herein refers to an ethyl group, the term “ter-Bu” or “But” as used herein refers to a tert-butyl group, and the term “OMe” as used herein refers to a methoxy group.

The term “biphenyl group” as used herein refers to “a phenyl group substituted with a phenyl group.” In other words, the “biphenyl group” may be a substituted phenyl group having a C₆-C₆₀ aryl group as a substituent.

The term “terphenyl group” as used herein refers to “a phenyl group substituted with a biphenyl group.” In other words, the “terphenyl group” may be a substituted phenyl group having, as a substituent, a C₆-C₆₀ aryl group substituted with a C₆-C₆₀ aryl group.

### EXAMPLES

### Comparative Example 1

As shown in FIG. 3, the first pixel electrode 410 and the second pixel electrode 510 were formed on the substrate 601, and the pixel defining film 405 was defined at edges of the pixel electrodes.

On the first pixel electrode 410 and the second pixel electrode 510, a p-doped hole transport layer (HT3 doped with HAT-CN (1 vol %)) having a thickness of 100 Å was formed as a common layer, and then, a hole transport layer having a thickness of 1,200 Å was formed by using HT3.

Subsequently, as a common layer, an optical auxiliary layer having a thickness of 300 Å was formed by using HT41.

In a photodetection region on the optical auxiliary layer, D-14, which is a p-type semiconductor compound, was deposited at a rate of 4.0 Å/s to form a layer having a thickness of 100 Å, and then, A−1, which is an n-type semiconductor compound, was deposited at a rate of 4.0 Å/s to form a layer having a thickness of 300 Å, thereby forming an activation layer.

Meanwhile, in an emission region on the optical auxiliary layer, 9,10-di-naphthalene-2-yl-anthracene (hereinafter, referred to as ADN), which is a blue fluorescent host, and N,N,N′,N′-tetraphenyl-pyrene-1,6-diamine (TPD), which is a blue fluorescent dopant compound, were co-deposited at a weight ratio of 98:2 to form an emission layer having a thickness of 300 Å.

Subsequently, BAlq was vacuum-deposited to form a buffer layer having a thickness of 50 Å, as a common layer, and ET1 was vacuum-deposited on the buffer layer to form an electron transport layer having a thickness of 300 Å, as a common layer.

MgAg (doping ratio of Mg: 5 wt %) was deposited on the electron transport layer to form a cathode having a thickness of 100 Å, as a common layer, thereby completing the manufacture of an in-cell-type electronic apparatus including an organic photodetector and a light-emitting device.

### Comparative Examples 2 to 8

Electronic apparatuses were manufactured in the same manner as in Comparative Example 1, except that corresponding p-type semiconductor compounds and n-type semiconductor compounds shown in Table 1 were used to form an activation layer.

### Examples 1 to 8

Electronic apparatuses were manufactured in the same manner as in Comparative Example 1, except that corresponding p-type semiconductor compounds (donors) and n-type semiconductor compounds (acceptors) shown in Table 1 were used to form an activation layer, wherein, when using a p-type semiconductor compound (donor), deposition was performed at a rate of 4.0 Å/s, and when using an n-type semiconductor compound (acceptor), deposition was performed at a rate of 0.5 Å/s, to form each layer.

External quantum efficiency (EQE) with respect to a wavelength of 530 nm, which is the peak wavelength of the organic photodetectors of the electronic apparatuses manufactured in Comparative Examples 1 to 8 and Examples 1 to 8, was measured.

In addition, LUMO energy values of the n-type semiconductor compounds (acceptors), differences in LUMO energy value between the layers consisting of the n-type semiconductor compounds and the buffer layers, and R_{q} values of surfaces of the layers consisting of the n-type semiconductor compounds (acceptors) in contact with the buffer layers were measured, and the results are shown in Table 1.

The LUMO energy values were calculated by using the density functional theory (DFT), the R_{q} values were calculated by using an atomic force microscope (AFM), and the EQE was measured by applying a reverse voltage of 3 V with a quantum efficiency meter using a Xe lamp and a source meter.

TABLE 1

| | | | | Acceptor | | |
|---|---|---|---|---|---|---|
| | | | | layer/buffer | EQE | |
| | | | Acceptor | layer LUMO | (%) | |
| | | | LUMO | energy | @ - | R_{q} |
| | Donor | Acceptor | eV | barrier | 3 V | (nm) |
| Comparative | D-14 | A-1 | −3.75 | 1.01 | 1.53 | 3.68 |
| Example 1 | | | | | | |
| Comparative | D-14 | A-9 | −3.49 | 0.75 | 19.29 | 8.71 |
| Example 2 | | | | | | |
| Comparative | D-14 | A-3 | −3.69 | 0.95 | 4.56 | 5.10 |
| Example 3 | | | | | | |
| Comparative | D-14 | A-17 | −4.14 | 1.40 | 4.28 | 6.31 |
| Example 4 | | | | | | |
| Comparative | D-4 | A-1 | −3.75 | 1.01 | 1.77 | 3.29 |
| Example 5 | | | | | | |
| Comparative | D-4 | A-9 | −3.49 | 0.75 | 22.82 | 7.52 |
| Example 6 | | | | | | |
| Comparative | D-4 | A-3 | −3.69 | 0.95 | 4.28 | 4.86 |
| Example 7 | | | | | | |
| Comparative | D-4 | A-17 | −4.14 | 1.40 | 5.73 | 5.95 |
| Example 8 | | | | | | |
| Example 1 | D-14 | A-1 | −3.75 | 1.01 | 42.8 | 9.24 |
| Example 2 | D-14 | A-9 | −3.49 | 0.75 | 41.44 | 10.9 |
| Example 3 | D-14 | A-3 | −3.69 | 0.95 | 48.83 | 11.40 |
| Example 4 | D-14 | A-17 | −4.14 | 1.40 | 6.99 | 10.23 |
| Example 5 | D-4 | A-1 | −3.75 | 1.01 | 36.55 | 9.51 |
| Example 6 | D-4 | A-9 | −3.49 | 0.75 | 32.96 | 11.20 |
| Example 7 | D-4 | A-3 | −3.69 | 0.95 | 36.79 | 13.16 |
| Example 8 | D-4 | A-17 | −4.14 | 1.40 | 10.19 | 10.60. |

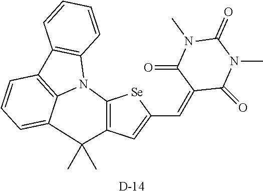

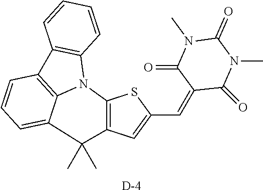

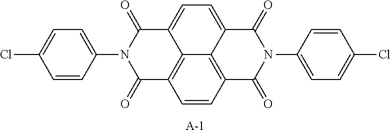

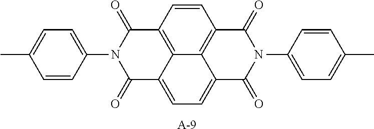

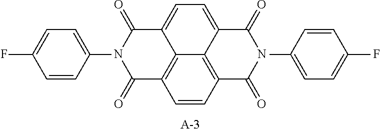

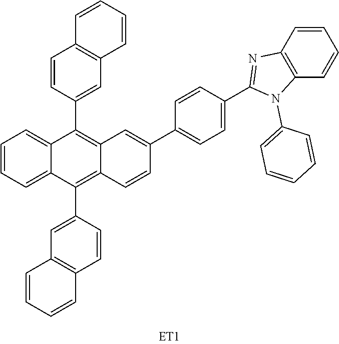 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

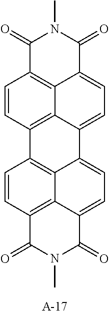

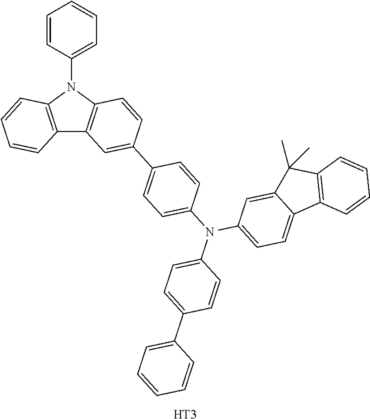

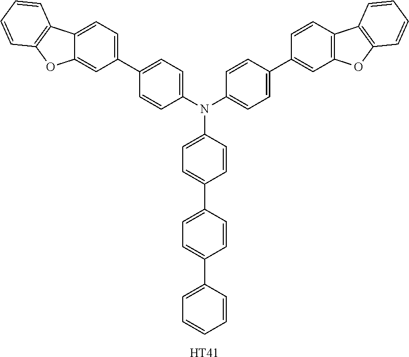

Referring to Table 1, Examples showed higher EQE than Comparative Examples in the same device structure. For example, Example 1 showed better results (i.e., higher EQE) than Comparative Example 1, Example 5 showed better results than Comparative Example 5, and Example 8 showed better results than Comparative Example 8.

Meanwhile, it was confirmed that the R_{q} values of the surfaces of the buffer layers and the electron transport layers in the electron transport regions of the organic photodetectors were all greater than 9 nm, and the R_{q} values of top and bottom surfaces of the counter electrode cathodes were also greater than 9 nm.

It was confirmed that the R_{q} values of the interfaces between the layers including the p-type semiconductor compounds and the layers including the n-type semiconductor compounds in the activation layers of the organic photodetectors of Examples were less than 5 nm. In addition, it was confirmed that the R_{q} values of the top and bottom surfaces of the buffer layers and the emission layers of the light-emitting devices of Examples were less than 5 nm.

Meanwhile, referring to Table 1, even when the same n-type semiconductor compound (acceptor) was used, the measured R_{q} values were slightly different from each other (e.g., Comparative Examples 1 and 5 and Examples 1 and 5). This is because different p-type semiconductor compounds (donors) were used, as shown below.

In Examples and Comparative Examples above, layers for which a specific deposition rate is not described were formed at a general deposition rate used in the art.

According to the one or more embodiments, an organic photodetector may have excellent efficiency.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made without departing from the spirit and scope as defined by the following claims.

What is claimed is:

1. An electronic apparatus comprising:
a substrate comprising a photodetection region and an emission region;
an organic photodetector arranged on the photodetection region; and
a light-emitting device arranged on the emission region,
wherein the organic photodetector comprises: a first pixel electrode; a counter electrode facing the first pixel electrode; and a hole transport region, an activation layer, and an electron transport region sequentially arranged between the first pixel electrode and the counter electrode,
the light-emitting device comprises: a second pixel electrode; the counter electrode facing the second pixel electrode; and the hole transport region, an emission layer, and the electron transport region sequentially arranged between the second pixel electrode and the counter electrode,
the first pixel electrode and the activation layer are arranged in the photodetection region,
the second pixel electrode and the emission layer are arranged in the emission region,
the hole transport region, the electron transport region, and the counter electrode are arranged in the photodetection region and the emission region, and
the electron transport region and the activation layer of the organic photodetector are in contact with each other, and a mean square roughness (R_{q}) value of a surface of the activation layer that is closest to the electron transport region is 9 nm or more.

2. The electronic apparatus of claim 1, wherein the hole transport region comprises a hole injection layer, a hole transport layer, an electron blocking layer, an auxiliary layer, or any combination thereof.

3. The electronic apparatus of claim 1, wherein the electron transport region comprises a buffer layer, a hole blocking layer, an electron transport layer, an electron injection layer, or any combination thereof.

4. The electronic apparatus of claim 1, wherein
the activation layer is a mixed layer comprising a p-type semiconductor compound and an n-type semiconductor compound; or
a layer comprising a p-type semiconductor compound and a layer comprising an n-type semiconductor compound, and the layer comprising the n-type semiconductor compound is in contact with the electron transport region.

5. The electronic apparatus of claim 1, wherein the electron transport region of the organic photodetector comprises a buffer layer, a hole blocking layer, an electron transport layer, an electron injection layer, or any combination thereof, and
one layer of the electron transport region is in contact with the activation layer.

6. The electronic apparatus of claim 1, wherein the electron transport region of the organic photodetector comprises a buffer layer, a hole blocking layer, an electron transport layer, an electron injection layer, or any combination thereof, and
a mean square roughness (R_{q}) value of a surface of each layer of the electron transport region is 9 nm or more.

7. The electronic apparatus of claim 1, wherein mean square roughness (R_{q}) values of top and bottom surfaces of the counter electrode above the first pixel electrode are each 9 nm or more.

8. The electronic apparatus of claim 1, wherein mean square roughness (R_{q}) values of top and bottom surfaces of the counter electrode above the second pixel electrode are each less than 5 nm.

9. The electronic apparatus of claim 1, wherein the activation layer comprises: a layer comprising a p-type semiconductor compound; and a layer comprising an n-type semiconductor compound,
the layer comprising the p-type semiconductor compound and the layer comprising the n-type semiconductor compound are in direct contact with each other, and
a mean square roughness (R_{q}) value of a surface of the layer comprising the p-type semiconductor compound in contact with the layer comprising the n-type semiconductor compound is less than 5 nm.

10. The electronic apparatus of claim 1, wherein the electron transport region and the emission layer of the light-emitting device are in contact with each other, and a mean square roughness (R_{q}) value of a surface of the emission layer that is closest to the electron transport region is less than 5 nm.

11. The electronic apparatus of claim 1, wherein the activation layer comprises a layer comprising an n-type semiconductor compound, and
a lowest unoccupied molecular orbital (LUMO) energy value of the layer is greater than −4.50 eV and less than −3.20 eV.

12. The electronic apparatus of claim 1, wherein the activation layer comprises: a layer comprising a p-type semiconductor compound; and a layer comprising an n-type semiconductor compound,
the layer comprising the n-type semiconductor compound is in contact with the electron transport region arranged between the first pixel electrode and the counter electrode, and
a difference between a LUMO energy value of a layer in the electron transport region in contact with the layer comprising the n-type semiconductor compound and a LUMO energy value of the layer comprising the n-type semiconductor compound is 0.3 eV or more.

13. The electronic apparatus of claim 12, wherein the LUMO energy value of the layer in the electron transport region in contact with the layer comprising the n-type semiconductor compound is greater than the LUMO energy value of the layer comprising the n-type semiconductor compound.

14. The electronic apparatus of claim 12, wherein the layer in the electron transport region in contact with the layer comprising the n-type semiconductor compound is a buffer layer or an electron transport layer.

15. The electronic apparatus of claim 1, wherein the electron transport region arranged throughout the photodetection region and the emission region comprises an electron transport layer,
mean square roughness (R_{q}) values of top and bottom surfaces of the electron transport layer of the light-emitting device are each less than 5 nm, and
mean square roughness (R_{q}) values of top and bottom surfaces of the electron transport layer of the organic photodetector are each 9 nm or more.

16. The electronic apparatus of claim 15, wherein a thickness of the electron transport layer of the light-emitting device is in a range of about 100 Å to about 3,000 Å.

17. The electronic apparatus of claim 1, wherein the activation layer comprises a p-type semiconductor compound, and
the p-type semiconductor compound comprises a compound represented by Formula 1: 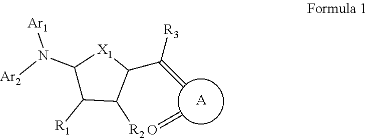
wherein, in Formula 1,
X₁ is O, S, Se, Te, SO, SO₂, CR₁₁R₁₂, or SiR₁₃R₁₄,
A is a C₃-C₆₀ carbocyclic group unsubstituted or substituted with at least one R₁₀ₐ or a C₁-C₆₀ heterocyclic group unsubstituted or substituted with at least one R₁₀ₐ,
R₁, R₂, and R₃, R₁, R₁₂, R₁₃, and R₁₄, Ar₁, and Ar₂ are each independently hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁, Q₂, and Q₃, Q₁₁, Q₁₂, and Q₁₃, Q₂₁, Q₂₂, and Q₂₃, and Q₃₁ to Q₃₂ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₅-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof, and
neighboring substituents among R₁, R₂, R₃, R₁₁, R₁₂, R₁₃, R₁₄, Ar₁, and Ar₂ are optionally bonded to each other to form a ring.

18. The electronic apparatus of claim 17, wherein the p-type semiconductor compound comprises one of compounds below:

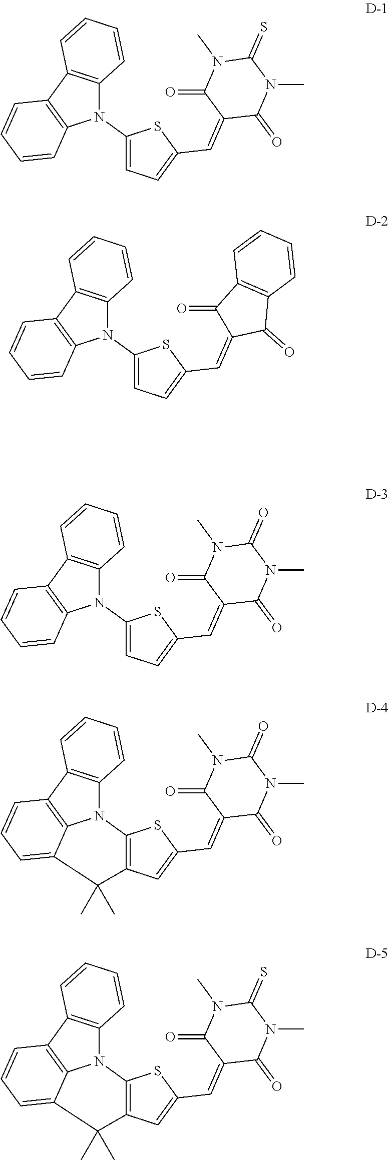 [SMILES: CN1C(=O)C(=Cc2ccc(-n3c4ccccc4c4ccccc43)s2)C(=O)N(C)C1=S ; O=C1C(=Cc2ccc(-n3c4ccccc4c4ccccc43)s2)C(=O)c2ccccc21 ; CN1C(=O)C(=Cc2ccc(-n3c4ccccc4c4ccccc43)s2)C(=O)N(C)C1=O ; CN1C(=O)C(=Cc2cc3c(s2)-n2c4ccccc4c4cccc(c42)C3(C)C)C(=O)N(C)C1=O ; CN1C(=O)C(=Cc2cc3c(s2)-n2c4ccccc4c4cccc(c42)C3(C)C)C(=O)N(C)C1=S]

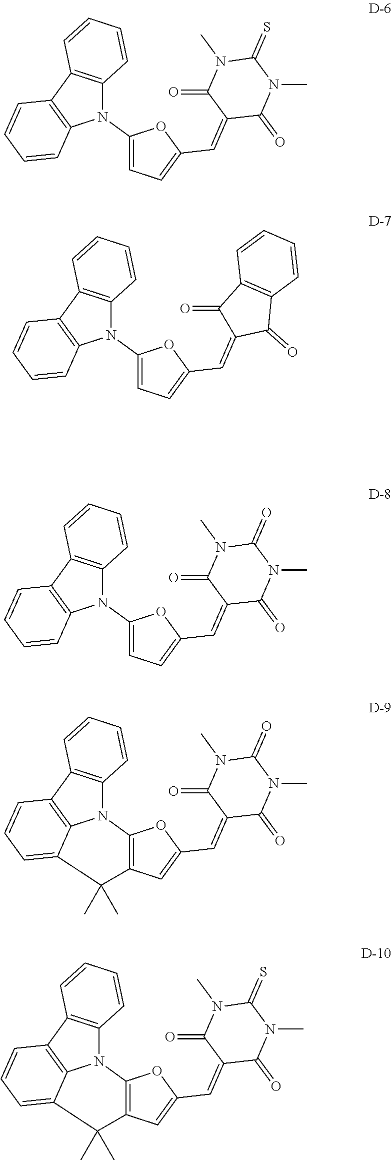 [SMILES: CN1C(=O)C(=Cc2ccc(-n3c4ccccc4c4ccccc43)o2)C(=O)N(C)C1=S ; O=C1C(=Cc2ccc(-n3c4ccccc4c4ccccc43)o2)C(=O)c2ccccc21 ; CN1C(=O)C(=Cc2ccc(-n3c4ccccc4c4ccccc43)o2)C(=O)N(C)C1=O ; CN1C(=O)C(=Cc2cc3c(o2)-n2c4ccccc4c4cccc(c42)C3(C)C)C(=O)N(C)C1=O ; CN1C(=O)C(=Cc2cc3c(o2)-n2c4ccccc4c4cccc(c42)C3(C)C)C(=O)N(C)C1=S]

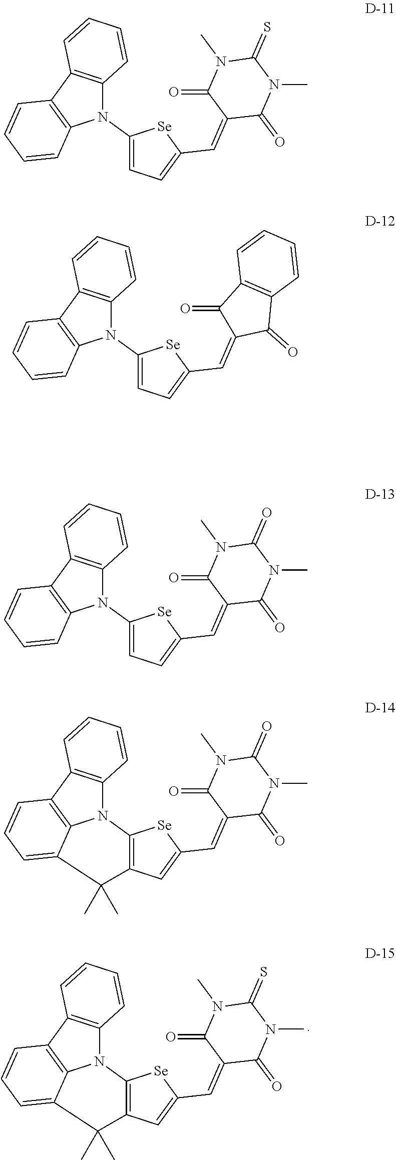 [SMILES: CN1C(=O)C(=Cc2ccc(-n3c4ccccc4c4ccccc43)[se]2)C(=O)N(C)C1=S ; O=C1C(=Cc2ccc(-n3c4ccccc4c4ccccc43)[se]2)C(=O)c2ccccc21 ; CN1C(=O)C(=Cc2ccc(-n3c4ccccc4c4ccccc43)[se]2)C(=O)N(C)C1=O ; CN1C(=O)C(=Cc2cc3c([se]2)-n2c4ccccc4c4cccc(c42)C3(C)C)C(=O)N(C)C1=O ; CN1C(=O)C(=Cc2cc3c([se]2)-n2c4ccccc4c4cccc(c42)C3(C)C)C(=O)N(C)C1=S]

19. The electronic apparatus of claim 1, wherein the activation layer comprises an n-type semiconductor compound, and
the n-type semiconductor compound comprises a compound represented by Formula 2 or 3: 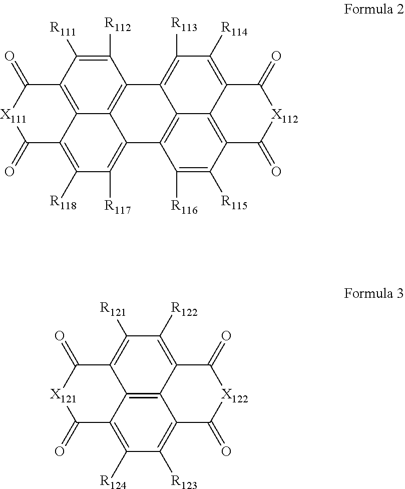
wherein, in Formula 2,
X₁₁₁ and X₁₁₂ are each independently O or NR₁₁₉, and
R₁₁₁, R₁₁₂, R₁₁₃, R₁₁₄, R₁₁₅, R₁₁₆, R₁₁₇, R₁₁₈, and R₁₁₉ are each independently hydrogen, deuterium, a halogen, a cyano group, a nitro group, a hydroxy group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or any combination thereof,
wherein, in Formula 3,
X₁₂₁ and X₁₂₂ are each independently O or NR₁₂₅, and
R₁₂₁, R₁₂₂, R₁₂₃, R₁₂₄, and R₁₂₅ are each independently hydrogen, deuterium, a halogen, a cyano group, a nitro group, a hydroxy group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or any combination thereof,
wherein, in Formulae 2 and 3,
R₁₀ₐ is:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, or a C₁-C₆₀ heteroarylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁, Q₁₂, and Q₁₃, Q₂₁, Q₂₂, and Q₂₃, Q₃₁ and Q₃₂ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

20. The electronic apparatus of claim 19, wherein the n-type semiconductor compound comprises one of compounds below: 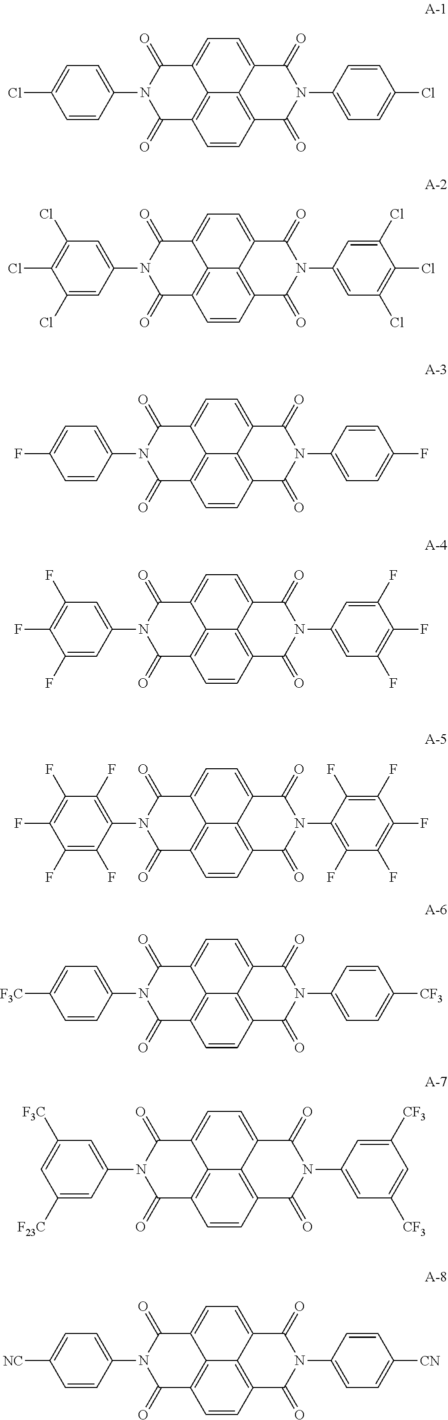 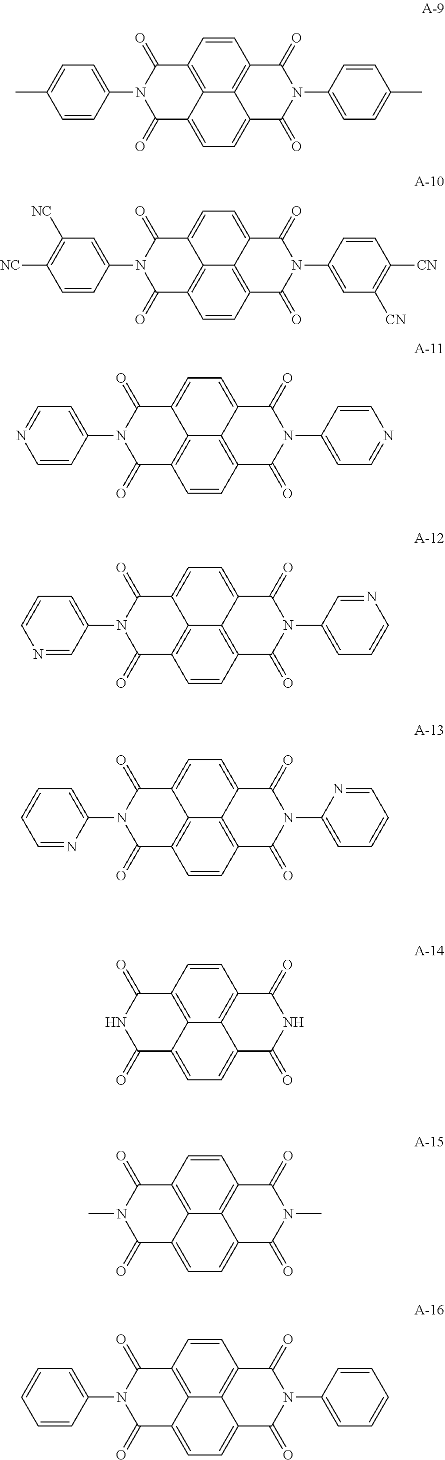 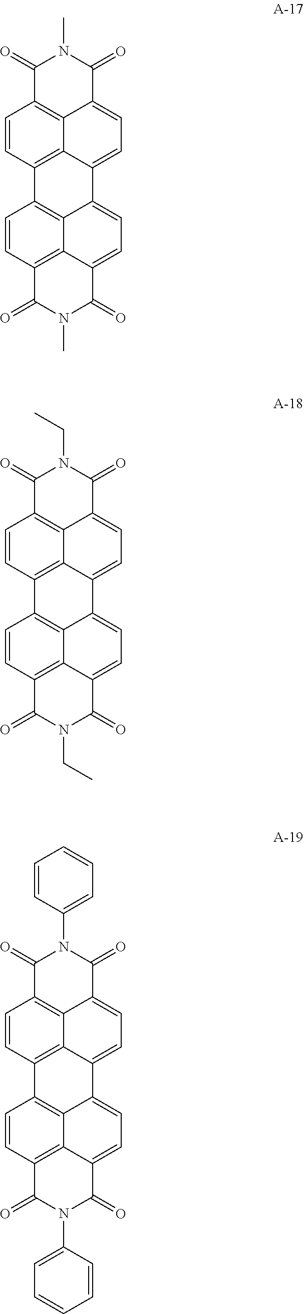 [SMILES: CN1C(=O)c2ccc3c4ccc5c6c(ccc(c7ccc(c2c37)C1=O)c64)C(=O)N(C)C5=O ; CCN1C(=O)c2ccc3c4ccc5c6c(ccc(c7ccc(c2c37)C1=O)c64)C(=O)N(CC)C5=O ; O=C1c2ccc3c4ccc5c6c(ccc(c7ccc(c2c37)C(=O)N1c1ccccc1)c64)C(=O)N(c1ccccc1)C5=O] 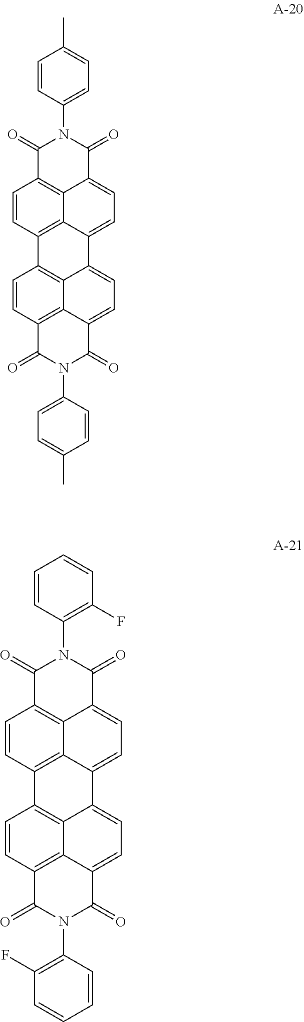 [SMILES: Cc1ccc(N2C(=O)c3ccc4c5ccc6c7c(ccc(c8ccc(c3c48)C2=O)c75)C(=O)N(c2ccc(C)cc2)C6=O)cc1 ; O=C1c2ccc3c4ccc5c6c(ccc(c7ccc(c2c37)C(=O)N1c1ccccc1F)c64)C(=O)N(c1ccccc1F)C5=O] 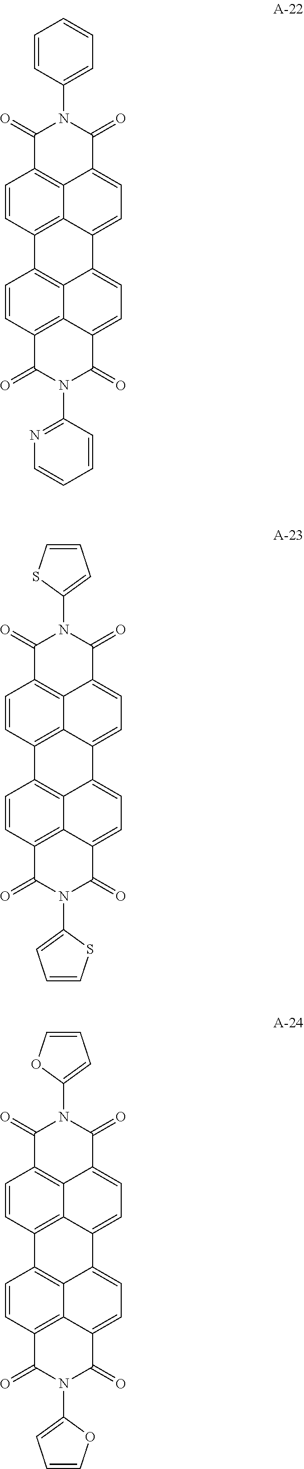 [SMILES: O=C1c2ccc3c4ccc5c6c(ccc(c7ccc(c2c37)C(=O)N1c1ccccc1)c64)C(=O)N(c1ccccn1)C5=O ; O=C1c2ccc3c4ccc5c6c(ccc(c7ccc(c2c37)C(=O)N1c1cccs1)c64)C(=O)N(c1cccs1)C5=O ; O=C1c2ccc3c4ccc5c6c(ccc(c7ccc(c2c37)C(=O)N1c1ccco1)c64)C(=O)N(c1ccco1)C5=O]
